(19) United States
(12) Patent Application Publication
(10) Pub. No.: US 2025/0102718 A1
(43) Pub. Date: Mar. 27, 2025

(54) POLARIZING PLATE, APPARATUS, HEAD-MOUNTED DISPLAY, ORGANIC ELECTROLUMINESCENT DISPLAY DEVICE, AND IMAGING SYSTEM

(71) Applicant: FUJIFILM Corporation, Tokyo (JP)

(72) Inventors: Ayako MURAMATSU, Kanagawa (JP); Mayumi NOJIRI, Kanagawa (JP); Makoto KAMO, Kanagawa (JP); Ryoji HIMENO, Kanagawa (JP); Tetsuro MITSUI, Kanagawa (JP)

(73) Assignee: FUJIFILM Corporation, Tokyo (JP)

(21) Appl. No.: 18/921,862

(22) Filed: Oct. 21, 2024

Related U.S. Application Data
(63) Continuation of application No. PCT/JP2023/017177, filed on May 2, 2023.

(30) Foreign Application Priority Data
May 6, 2022 (JP) 2022-076504
Nov. 9, 2022 (JP) 2022-179635

(51) Int. Cl. G02B 5/30

(52) U.S. Cl. CPC G02B 5/3025

(57) ABSTRACT

A polarizing plate that, when being applied to an apparatus in which at least one of a display element or a visible light imaging element and an infrared light sensing system are combined, detection performance of the infrared light sensing system is excellent, and display performance is excellent when the apparatus includes the display element or imaging performance is excellent when the apparatus includes the imaging element; an apparatus; a head-mounted display; an organic electroluminescent display device; and an imaging system. In the polarizing plate, an average transmittance at a wavelength of 400 to 700 nm is 70% or more, a maximum value of a polarization degree at a wavelength of 800 to 1500 nm is 80% or more, and when a wavelength at which the polarization degree is the maximum value is defined as a wavelength λ1, a transmittance T(λ1) at the wavelength λ1 satisfies predetermined relationships.

### CROSS-REFERENCE TO RELATED APPLICATIONS

This application is a Continuation of PCT International Application No. PCT/JP2023/017177 filed on May 2, 2023, which claims priority under 35 U.S.C. § 119(a) to Japanese Patent Application No. 2022-076504 filed on May 6, 2022 and Japanese Patent Application No. 2022-179635 filed on Nov. 9, 2022. The above applications are hereby expressly incorporated by reference, in their entirety, into the present application.

### BACKGROUND OF THE INVENTION

### 1. Field of the Invention

The present invention relates to a polarizing plate, an apparatus, a head-mounted display, an organic electroluminescent display device, and an imaging system.

### 2. Description of the Related Art

A polarizing plate having a light transmission and shielding function has been used for various applications.

In particular, in recent years, a polarizing plate used not only for a visible light region but also for an infrared light region has been demanded.

For example, JP2012-118237A proposes a polarizing plate exhibiting high polarization characteristics in an infrared light region.

### SUMMARY OF THE INVENTION

On the other hand, in recent years, from the viewpoint of multifunctionalization and space saving of an apparatus, an apparatus which uses a device for visible light, such as a display element for displaying an image and a visible light imaging element used for visible light imaging, and an infrared light sensing system in combination has been developed. For example, an image display apparatus such as an organic electroluminescent display device may include a display element which displays an image viewed by a user, and an infrared light sensing system including an infrared light source and an infrared light receiving section for performing face authentication of the user. In such an image display apparatus, the polarizing plate is disposed on a viewing side of the image display apparatus for preventing reflection, and the polarizing plate is required not to deteriorate display performance of the display element and not to deteriorate detection performance of the infrared light sensing system. That is, it is required that the display performance of the display element and the detection performance of the infrared light sensing system are excellent. In other words, it is required that both the display performance of the display element and the detection performance of the infrared light sensing system are achieved.

In addition to the above, in an apparatus including a visible light imaging element and an infrared light sensing system, it is required that a polarizing plate used in the device has excellent imaging performance of the visible light imaging element and detection performance of the infrared light sensing system. In other words, it is required that both the imaging performance of the visible light imaging element and the detection performance of the infrared light sensing system are achieved.

As a result of studying the characteristics of the polarizing plate disclosed in JP2012-118237A, the present inventors have found that the above-described desired effects are not obtained.

In view of the above-described circumstances, an object of the present invention is to provide a polarizing plate that, in a case of being applied to an apparatus in which at least one of a display element or a visible light imaging element and an infrared light sensing system are combined, detection performance of the infrared light sensing system is excellent, and display performance is excellent in a case where the apparatus includes the display element or imaging performance is excellent in a case where the apparatus includes the imaging element.

Another object of the present invention is to provide an apparatus, a head-mounted display, an organic electroluminescent display device, and an imaging system.

As a result of intensive studies on the problems in the related art, the present inventors have found that the above-described objects can be accomplished by the following configurations.

(1) A polarizing plate,
in which an average transmittance at a wavelength of 400 to 700 nm is 70% or more,
a maximum value of a polarization degree at a wavelength of 800 to 1500 nm is 80% or more, and
in a case where a wavelength at which the polarization degree is the maximum value is defined as a wavelength λ1, a transmittance T(λ1) at the wavelength λ1 satisfies relationships of an expression (A1) and an expression (A2),

| | |
|---|---|
| the expression (A1) | 30% ≤ T(λ1), and |
| the expression (A2) | T(λ1) ≤ 50%. |

(2) The polarizing plate according to (1),
in which a relationship of an expression (A3) is satisfied,

| | |
|---|---|
| the expression (A3) | 40% ≤ T(λ1). |

(3) The polarizing plate according to (1) or (2),
in which a relationship of an expression (A4) is satisfied,

| | |
|---|---|
| the expression (A4) | T(λ1) ≤ 45%. |

(4) The polarizing plate according to any one of (1) to (3),
in which the polarizing plate contains a dichroic coloring agent having a maximal absorption wavelength at the wavelength of 800 to 1500 nm, and
an alignment degree S(λ1) of the dichroic coloring agent at the wavelength λ1 satisfies relationships of an expression (B1) and an expression (B2),

| | |
|---|---|
| the expression (B1) | 0.700 ≤ S(λ1), and |
| the expression (B2) | S(λ1) ≤ 0.950. |

(5) The polarizing plate according to (4),
in which a relationship of an expression (B3) is satisfied,

| | |
|---|---|
| the expression (B3) | 0.850 ≤ S(λ1). |

(6) The polarizing plate according to (4) or (5),
in which a relationship of an expression (B4) is satisfied,

| | |
|---|---|
| the expression (B4) | S(λ1) ≤ 0.930. |

(7) An apparatus comprising:
the polarizing plate according to any one of (1) to (6);
at least one of a display element or a visible light imaging element; and
an infrared light receiving section.

(8) An apparatus according to (7), further comprising:
an infrared light source,
in which a difference between the λ1 and a maximal wavelength λ2 of an infrared light emitted from the infrared light source is 20 nm or less.

(9) A head-mounted display comprising:
the apparatus according to (7).

(10) An organic electroluminescent display device comprising:
the apparatus according to (7).

(11) An imaging system comprising:
the apparatus according to (7).

(12) An apparatus comprising:
the polarizing plate according to any one of (1) to (6);
an infrared light and visible light dual-purpose imaging element; and
an infrared light source.

(13) An apparatus according to (12), further comprising:
an infrared light source,
in which a difference between the λ1 and a maximal wavelength λ2 of an infrared light emitted from the infrared light source is 20 nm or less.

According to the present invention, it is possible to provide a polarizing plate that, in a case of being applied to an apparatus in which at least one of a display element or a visible light imaging element and an infrared light sensing system are combined, detection performance of the infrared light sensing system is excellent, and display performance is excellent in a case where the apparatus includes the display element or imaging performance is excellent in a case where the apparatus includes the imaging element.

In addition, according to the present invention, it is possible to provide an apparatus, a head-mounted display, an organic electroluminescent display device, and an imaging system.

### BRIEF DESCRIPTION OF THE DRAWINGS

FIG. 1 is a schematic view for describing an organic electroluminescent (EL) display device including a polarizing plate according to an embodiment of the present invention.

FIG. 2 is a schematic view for describing a head-mounted display including the polarizing plate according to the embodiment of the present invention.

FIG. 3 is a schematic view of an apparatus used for evaluation of an iris detection of Examples.

FIG. 4 is a view for describing an imaging system.

### DESCRIPTION OF THE PREFERRED EMBODIMENTS

Hereinafter, the present invention will be described in detail.

In the present specification, a numerical range expressed using “to” means a range that includes the proceeding and succeeding numerical values of “to” as a lower limit value and an upper limit value, respectively.

In addition, unless otherwise specified, a slow axis and a fast axis are defined at a wavelength of 550 nm. That is, unless otherwise specified, for example, a slow axis direction means a direction of a slow axis at a wavelength of 550 nm.

In the present invention, Re(λ) and Rth(λ) represent an in-plane retardation at a wavelength λ and a thickness direction retardation at a wavelength λ, respectively. Unless otherwise specified, the wavelength λ is 550 nm.

In the present invention, Re(λ) and Rth(λ) are values measured at the wavelength λ in AxoScan OPMF-1 (manufactured by Opto Science, Inc.). By inputting an average refractive index ((nx+ny+nz)/3) and a film thickness (d (μm)) in AxoScan, a slow axis direction (°), Re(λ)=R0(λ), and Rth(λ)=((nx+ny)/2−nz)×d are calculated.

In addition, R0(λ) is expressed in a numerical value calculated with AxoScan OPMF-1, and means Re(λ).

In the present specification, the refractive indices nx, ny, and nz are measured using an Abbe refractometer (NAR-4T, manufactured by Atago Co., Ltd.) and using a sodium lamp (λ=589 nm) as a light source. In addition, in a case of measuring wavelength dependence, it can be measured with a multi-wavelength Abbe refractometer DR-M2 (manufactured by Atago Co., Ltd.) in combination with a dichroic filter.

In addition, values in Polymer Handbook (John Wiley & Sons, Inc.) and catalogs of various optical films can be used. The values of the average refractive index of main optical films are exemplified below: cellulose acylate (1.48), cycloolefin polymer (1.52), polycarbonate (1.59), polymethylmethacrylate (1.49), and polystyrene (1.59).

In addition, in the present specification, a relationship between angles (for example, “orthogonal”, “parallel”, and the like) is intended to include a range of errors acceptable in the art to which the present invention belongs. For example, it means that an angle is in an error range of ±5° with respect to the exact angle, and the error with respect to the exact angle is preferably in a range of ±3°.

A bonding direction of a divalent group (for example, —COO—) described in the present specification is not particularly limited. For example, in a case where L in X-L-Y is —COO— and in a case where the position bonded to the X side is defined as *1 and the position bonded to the Y side is defined as *2, L may be *1-O—CO—*2 or *1-CO—O—*2.

A feature point of the polarizing plate according to the embodiment of the present invention is that various characteristics in a visible light region having a wavelength of 400 to 700 nm and in an infrared light region having a wavelength of 800 to 1,500 nm are adjusted to a predetermined range.

<Polarizing plate>

In the polarizing plate according to the embodiment of the present invention, an average transmittance at a wavelength of 400 to 700 nm is 70% or more, a maximum value of a polarization degree at a wavelength of 800 to 1,500 nm is 80% or more, and in a case where a wavelength at which the polarization degree is the maximum value is defined as a wavelength λ1, a transmittance T(λ1) at the wavelength λ1 satisfies relationships of an expression (A1) and an expression (A2) described later.

Hereinafter, features of the polarizing plate will be described.

The average transmittance of the polarizing plate according to the embodiment of the present invention at a wavelength of 400 to 700 nm is 70% or more, and from the viewpoint that the performance of the display performance or the imaging performance is more excellent, it is preferably 80% or more, and more preferably 90% or more. The upper limit of the above-described average transmittance is not particularly limited, but is usually 98% or less.

The above-described average transmittance is obtained by measuring a transmittance of the polarizing plate for each wavelength at 1 nm intervals in a wavelength range of 400 to 700 nm using an ultraviolet-visible-near infrared spectrophotometer (for example, an ultraviolet-visible-near infrared spectrophotometer V-660), and arithmetically averaging the obtained transmittance at each wavelength.

The maximum value of the polarization degree of the polarizing plate according to the embodiment of the present invention at a wavelength of 800 to 1,500 nm is 80% or more, and from the viewpoint that the detection performance of the infrared light sensing system is more excellent, it is preferably 90% or more, and more preferably 95% or more. The upper limit of the above-described maximum value of the polarization degree is not particularly limited, but is usually less than 100% and more usually 99.9% or less.

The above-described maximum value of the polarization degree is obtained by measuring a transmittance Tz(λ) of the polarizing plate in an absorption axis direction with respect to polarization at a wavelength λ and a transmittance Ty(λ) of the polarizing plate in a transmission axis direction with respect to the polarization at the wavelength λ in a wavelength range of 400 to 1,500 nm using an ultraviolet-visible-near infrared spectrophotometer (for example, an ultraviolet-visible-near infrared spectrophotometer V-660 equipped with an automatic absolute reflectivity measuring unit ARMN-735 manufactured by JASCO Corporation), obtaining a polarization degree P(λ) (%) by the following expression, and obtaining a maximum value thereof. The absorption axis and the transmission axis described above mean an absorption axis and a transmission axis of the polarizing plate at a maximal absorption wavelength.

$$P ( λ ) = \{ ( Ty ( λ ) - Tz ( λ ) ) / ( Ty ( λ ) + Tz ( λ ) ) \} \times 100$$

In the polarizing plate according to the embodiment of the present invention, in a case where a wavelength at which the polarization degree is the maximum value is defined as a wavelength λ1, a transmittance T(λ1) at the wavelength λ1 satisfies relationships of an expression (A1) and an expression (A2).

$$30 \% \leq T ( λ 1 ) \qquad Expression ( A1 )$$

$$T ( λ 1 ) \leq 50 \% \qquad Expression ( A2 )$$

Among these, from the viewpoint that the detection performance of the infrared light sensing system is more excellent, it is preferable to satisfy at least one of a relationship of an expression (A3) or a relationship of an expression (A4); and it is more preferable to satisfy both the relationship of the expression (A3) and the relationship of the expression (A4).

$$40 \% \leq T ( λ 1 ) \qquad Expression ( A3 )$$

$$T ( λ1 ) \leq 45 \% \qquad Expression ( A4 )$$

Various characteristics of the polarizing plate described above can be controlled by changing a material to be used (for example, a dichroic substance, a liquid crystal compound, and the like described later), adjusting an amount of the material to be used, or adjusting a method for manufacturing the polarizing plate described later. More specifically, for example, in a case where the polarizing plate contains a liquid crystal compound (for example, a lyotropic liquid crystal compound) described later, there is a method of increasing aligning properties (alignment degree) of the dichroic substance by increasing aligning properties of the liquid crystal compound, thereby increasing the above-described polarization degree.

### (Dichroic Substance)

The polarizing plate according to the embodiment of the present invention preferably contains a dichroic substance. The dichroic substance means a coloring agent having different absorbances depending on directions. The dichroic substance may or may not exhibit liquid crystallinity.

The dichroic substance is not particularly limited, and examples thereof include a dichroic coloring agent, a light emitting material (such as a fluorescent material or a phosphorescent material), an ultraviolet absorbing material, an infrared absorbing material, a non-linear optical material, a carbon nanotube, and an inorganic material (for example, a quantum rod, metal nanoparticles, and metal nanorods). In addition, known dichroic substances (dichroic coloring agents) of the related art can be used.

The polarizing plate according to the embodiment of the present invention preferably contains a dichroic coloring agent.

The dichroic coloring agent contained in the polarizing plate according to the embodiment of the present invention preferably has a maximal absorption wavelength at a wavelength of 800 to 1,500 nm.

The above-described maximal absorption wavelength of the dichroic coloring agent can be obtained by measuring an absorption spectrum of the dichroic coloring agent in the polarizing plate using an ultraviolet-visible-near infrared spectrophotometer (for example, an ultraviolet-visible-near infrared spectrophotometer V-660).

In the polarizing plate according to the embodiment of the present invention, the alignment degree S(λ1) of the dichroic coloring agent at the wavelength λ1 is not particularly limited, but from the viewpoint of more excellent detection performance of the infrared light sensing system or the viewpoint of more excellent workability of the polarizing plate, it is preferable to satisfy a relationship of an expression (B1) and a relationship of an expression (B2).

$$0.7 \leq S ( λ1 ) \qquad Expression ( B1 )$$

$$S ( λ1 ) \leq 0.95 \qquad Expression ( B2 )$$

Among these, it is preferable to satisfy at least one of a relationship of an expression (B3) or a relationship of an expression (B4); and it is more preferable to satisfy both the relationship of the expression (A3) and the relationship of the expression (A4).

$$0.85 \leq S ( λ1 ) \qquad Expression ( B3 )$$

$$S ( λ1 ) \leq 0.93 \qquad Expression ( B4 )$$

The above-described alignment degree S(λ1) of the dichroic coloring agent is obtained by measuring a transmittance Tz(λ) of the polarizing plate in an absorption axis direction with respect to polarization at the wavelength λ1 and a transmittance Ty(λ) of the polarizing plate in a transmission axis direction with respect to the polarization at the wavelength λ1 using an ultraviolet-visible-near infrared spectrophotometer (for example, an ultraviolet-visible-near infrared spectrophotometer V-660 equipped with an automatic absolute reflectivity measuring unit ARMN-735 manufactured by JASCO Corporation), and obtaining the alignment degree S(λ1) by the following expression. The absorption axis and the transmission axis described above mean an absorption axis and a transmission axis at a maximal absorption wavelength.

$$S = ( Az ( λ1 ) - Ay ( λ1 ) ) / \{ Az ( λ1 ) + ( 2 \times Ay ( λ1 ) ) \} \\ Ay ( λ1 ) = - Log ( Ty ( λ1 ) ) \\ Az ( λ1 ) = - Log ( Tz ( λ1 ) )$$

A method of adjusting the alignment degree of the dichroic coloring agent is not particularly limited, and as described above, in a case where the polarizing plate contains a liquid crystal compound (for example, a lyotropic liquid crystal compound) described later, aligning properties (alignment degree) of the dichroic coloring agent can be increased by increasing alignment properties of the liquid crystal compound.

The dichroic coloring agent may exhibit liquid crystallinity (for example, lyotropic liquid crystallinity) or may not exhibit the liquid crystallinity, but it is preferable that the dichroic coloring agent exhibits the liquid crystallinity.

In a case where the dichroic coloring agent exhibits the liquid crystallinity, any of nematic properties, smectic properties, or columnar properties may be exhibited.

The dichroic coloring agent preferably has a hydrophilic group. In a case where the dichroic coloring agent has a hydrophilic group, the polarizing plate according to the embodiment of the present invention can be easily manufactured by being used in combination with a non-colorable lyotropic liquid crystal compound described later.

Hereinafter, the dichroic coloring agent having a hydrophilic group is also referred to as a specific dichroic coloring agent.

Examples of the hydrophilic group include an acid group or a salt thereof, an onium base, a hydroxy group or a salt thereof, a sulfonamide group (H₂N—SO₂—), and a polyoxyalkylene group. Among these, an acid group or a salt thereof is preferable.

The onium base is a group derived from an onium salt, and examples thereof include an ammonium base (*—N+(R^{Z})₃A⁻), a phosphonium base (*—P⁺(R^{Z})₃A⁻), and a sulfonium base (*—S+(R^{Z})₂A⁻). R^{Z}'s each independently represent a hydrogen atom, an alkyl group, an aryl group, or a heteroaryl group. A⁻ represents an anion (for example, a halogen ion). * represents a bonding position.

The salt of the hydroxy group is represented by *—O⁻M⁺, in which M⁺ represents a cation and * represents a bonding position. Examples of the cation represented by M⁺ include a cation in a salt of an acid group, which will be described later.

Examples of the polyoxyalkylene group include a group represented by R^{Z}—(O-L^{Z})ₙ-*. R^{Z} is as described above. L^{Z} represents an alkylene group. * represents a bonding position.

Examples of the acid group or a salt thereof include a sulfo group (—SO₃H) or a salt thereof (—SO₃-M⁺; M⁺ represents a cation), and a carboxyl group (—COOH) or a salt thereof (˜COO⁻M⁺; M⁺ represents a cation), and from the viewpoint that alignment of the specific dichroic coloring agent in the polarizing plate is more excellent, a sulfo group or a salt thereof is preferable.

The above-described salt refers to a salt in which a hydrogen ion of the acid is replaced with another cation such as a metal ion. That is, the salt of the acid group refers to a salt in which the hydrogen ion of the acid group such as a —SO₃H group is replaced with another cation. Examples of the cation in the salt of the acid group (for example, a cation in the salt of a sulfo group and a cation in the salt of a carboxyl group) include Na⁺, K⁺, Li⁺, Rb⁺, Cs⁺, Ba²⁺, Ca²⁺, Mg²⁺, Sr²⁺, Pb²⁺, Zn²⁺, La³⁺, Ce³⁺, Y³⁺, Yb³⁺, Gd³⁺, and Zr⁴⁺. Among these, from the viewpoint that the alignment of the specific dichroic coloring agent in the polarizing plate is more excellent, an alkali metal ion is preferable; Na⁺, K⁺, or Li⁺ is more preferable; and Li⁺ is still more preferable.

As described above, the specific dichroic coloring agent preferably has a maximal absorption wavelength in a wavelength range of 800 to 1,500 nm. That is, the specific dichroic coloring agent is preferably a near-infrared absorbing dichroic coloring agent.

The type of the specific dichroic coloring agent (particularly, the near-infrared-absorbing dichroic coloring agent having a hydrophilic group) is not particularly limited, and examples thereof include known materials. Examples of the specific dichroic coloring agent include dichroic coloring agents having a hydrophilic group, and examples thereof include a phthalocyanine-based coloring agent having a hydrophilic group, a naphthalocyanine-based coloring agent having a hydrophilic group, a metal complex-based coloring agent having a hydrophilic group, a boron complex-based coloring agent having a hydrophilic group, a cyanine-based coloring agent having a hydrophilic group, an oxonol-based coloring agent having a hydrophilic group, a squarylium-based coloring agent having a hydrophilic group, a rylene-based coloring agent having a hydrophilic group, a diimonium-based coloring agent having a hydrophilic group, a diphenylamine-based coloring agent having a hydrophilic group, a triphenylamine-based coloring agent having a hydrophilic group, a quinone-based coloring agent having a hydrophilic group, and an azo-based coloring agent having a hydrophilic group. In general, these coloring agents extend an absorption wavelength to a long wavelength side by extending the existing π-conjugated system, and exhibit a wide variety of absorption wavelengths depending on their structure.

The definition of the hydrophilic group included in the coloring agents exemplified above (a phthalocyanine-based coloring agent having a hydrophilic group, a naphthalocyanine-based coloring agent having a hydrophilic group, a metal complex-based coloring agent having a hydrophilic group, a boron complex-based coloring agent having a hydrophilic group, a cyanine-based coloring agent having a hydrophilic group, an oxonol-based coloring agent having a hydrophilic group, a squarylium-based coloring agent having a hydrophilic group, a rylene-based coloring agent having a hydrophilic group, a diimonium-based coloring agent having a hydrophilic group, a diphenylamine-based coloring agent having a hydrophilic group, a triphenylamine-based coloring agent having a hydrophilic group, a quinone-based coloring agent having a hydrophilic group, and an azo-based coloring agent having a hydrophilic group) is as described above.

The phthalocyanine-based coloring agent having a hydrophilic group and the naphthalocyanine-based coloring agent having a hydrophilic group are coloring agents having a planar structure and having a wide π-conjugated plane.

The phthalocyanine-based coloring agent having a hydrophilic group preferably has a structure represented by Formula (1A), and the naphthalocyanine-based coloring agent having a hydrophilic group preferably has a structure represented by Formula (1).

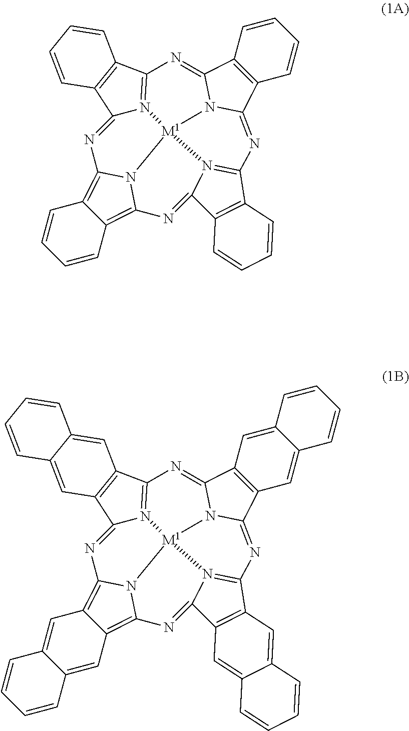

In Formula (1A) and Formula (1B), M¹ represents a hydrogen atom, a metal atom, a metal oxide, a metal hydroxide, or a metal halide.

Examples of the metal atom include Li, Na, K, Mg, Ti, Zr, V, Nb, Ta, Cr, Mo, W, Mn, Fe, Co, Ni, Ru, Rh, Pd, Os, Ir, Pt, Cu, Ag, Au, Zn, Cd, Hg, Al, Ga, In, Si, Ge, Sn, Pb, Sb, and Bi.

Examples of the metal oxide include VO, GeO, and TiO.

Examples of the metal hydroxide include Si(OH)₂, Cr(OH)₂, Sn(OH)₂, and AlOH.

Examples of the metal halide include SiCl₂, VCl, VCl₂, VOCl, FeCl, GaCl, ZrCl, and AlCl.

Among these, a metal atom such as Fe, Co, Cu, Ni, Zn, A1, and V, a metal oxide such as VO, or a metal hydroxide such as AlOH is preferable; and a metal oxide such as VO is more preferable.

The phthalocyanine-based coloring agent having a hydrophilic group is preferably a compound represented by Formula (1A-1).

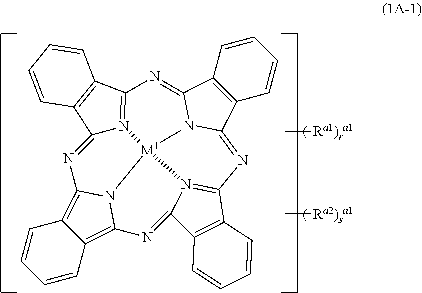

In Formula (1A-1), R^{a1}'s each independently represent a substituent having a hydrophilic group (hereinafter, also simply referred to as “specific substituent”). R^{a2}'s each independently represent a substituent not having a hydrophilic group.

The hydrophilic group included in the specific substituent is as described above.

The specific substituent is preferably a group represented by Formula (Z).

*-L^{a1}-(R^{a11})_{q} Formula(Z)

In Formula (Z), R^{a1} represents a hydrophilic group. The definition of the hydrophilic group is as described above.

In Formula (Z), in a case where q is 1, L^{a1} represents a single bond or a divalent linking group, and in a case where q is 2 or more, L^{a1} represents a (q+1)-valent linking group.

Examples of the divalent linking group include a divalent hydrocarbon group (for example, a divalent aliphatic hydrocarbon group such as an alkylene group (preferably having 1 to 10 carbon atoms and more preferably having 1 to 5 carbon atoms), an alkenylene group (preferably having 2 to 10 carbon atoms and more preferably having 2 to 5 carbon atoms), and an alkynylene group (preferably having 2 to 10 carbon atoms and more preferably having 2 to 5 carbon atoms), and a divalent aromatic hydrocarbon ring group such as an arylene group), a divalent heterocyclic group, —O—, —S—, —NH—, —N(Q)-, —CO—, and a group obtained by combining these groups (for example, —O-divalent hydrocarbon group-, —(O-divalent hydrocarbon group)ₘ-O-(m represents an integer of 1 or more), -divalent hydrocarbon group-O—CO—, and the like). Q represents a hydrogen atom or an alkyl group.

In a case where q is 2 or more, examples of the (q+1)-valent linking group represented by L^{a1} include a trivalent linking group (q=2) and a tetravalent linking group (q=3).

Examples of the tetravalent linking group include a residue formed by removing four hydrogen atoms from a hydrocarbon, a residue formed by removing four hydrogen atoms from a heterocyclic compound, and a group obtained by combining the residue and the above-described divalent linking group.

Examples of the tetravalent linking group include a residue formed by removing four hydrogen atoms from a hydrocarbon, a residue formed by removing four hydrogen atoms from a heterocyclic compound, and a group obtained by combining the residue and the above-described divalent linking group.

q represents an integer of 1 or more, and is preferably an integer of 1 to 4, more preferably 1 or 2, and still more preferably 1.

R^{a2}'s each independently represent a substituent not having a hydrophilic group. Examples of the above-described substituent not having a hydrophilic group include an alkyl group, an aryl group, and a heteroaryl group.

r^{a1} represents an integer of 1 or more, and is preferably an integer of 1 to 12 and more preferably an integer of 1 to 4.

s^{a1} represents an integer of 0 or more, and is preferably an integer of 0 to 4 and more preferably 0.

The naphthalocyanine-based coloring agent having a hydrophilic group is preferably a compound represented by Formula (1B-1).

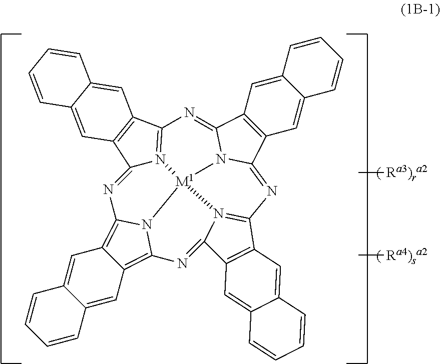

In Formula (1B-1), R^{a3}'s each independently represent a specific substituent. R^{a4}'s each independently represent a substituent not having a hydrophilic group.

The specific substituent represented by R^{a3} has the same meaning as the specific substituent represented by R^{a1}.

The substituent not having a hydrophilic group, represented by R^{a4}, has the same meaning as the substituent not having a hydrophilic group, represented by R².

r^{a2} represents an integer of 1 or more, and is preferably an integer of 1 to 12 and more preferably an integer of 1 to 4.

s^{a2} represents an integer of 0 or more, and is preferably an integer of 0 to 4 and more preferably 0.

The phthalocyanine-based coloring agent having a hydrophilic group is preferably the following compound example 1.

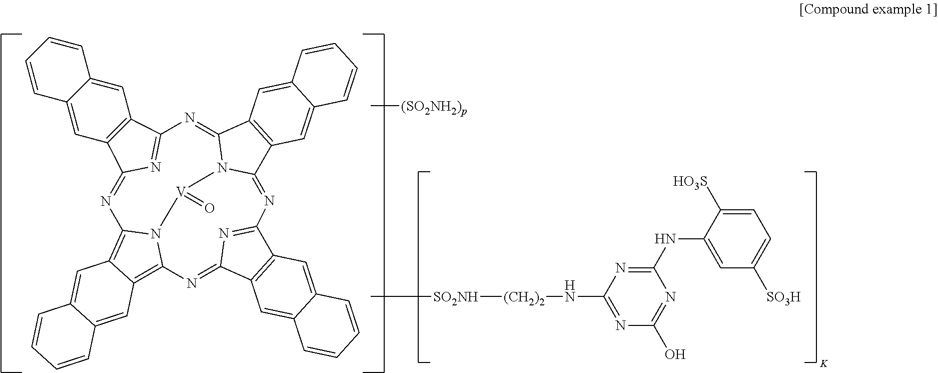

In the formula, p and k each independently represent an integer of 0 to 12, and the sum of p and k is 1 to 12. Among these, it is preferable that p is 1 to 4 and k is 0.

The quinone-based coloring agent having a hydrophilic group is a coloring agent having a wide range of absorption.

The quinone-based coloring agent having a hydrophilic group preferably has a structure represented by Formula (2).

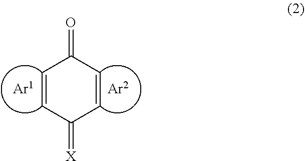

In Formula (2), X represents an oxygen atom or ═NR^{b}. R^{b} represents a hydrogen atom or a substituent. Examples of the substituent represented by R^{b} include groups exemplified by a substituent W described later.

Ar¹ and Ar² each independently represent an aromatic ring or a heterocyclic ring, and from the viewpoint of extending the absorption wavelength to a long wavelength side, a heterocyclic ring is preferable.

Since the quinone-based coloring agent has a hydrophilic group, the coloring agent can be dissolved in water. Examples of the quinone-based coloring agent having a hydrophilic group include indanthrene coloring agents described in JP2006-508034A.

The quinone-based coloring agent is preferably a compound represented by Formula (2-1).

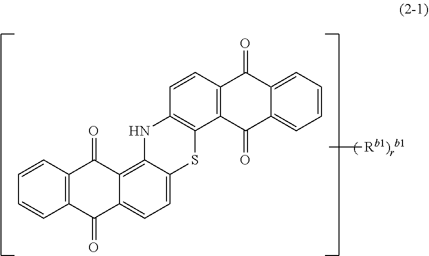

R^{b1}'s each independently represent a specific substituent. The specific substituent is as described above. In particular, a specific substituent of q=1 is preferable.

r^{b1} represents an integer of 1 to 12, and is preferably an integer of 1 to 4.

The quinone-based coloring agent having a hydrophilic group is preferably the following compound example 2.

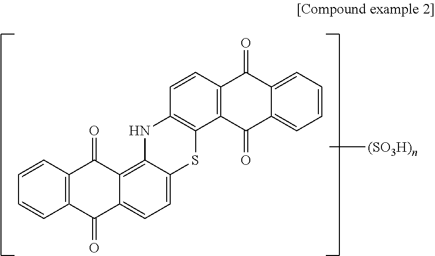

In the formula, n represents an integer of 1 to 12, and each sulfonic acid may be in a liberate form, in a salt for, or may include both the liberate form and the salt form in arbitrary ratio.

The cyanine-based coloring agent having a hydrophilic group is a coloring agent having strong absorption in a near-infrared region.

The cyanine-based coloring agent having a hydrophilic group is preferably a compound represented by Formula (3) or a compound represented by Formula (4).

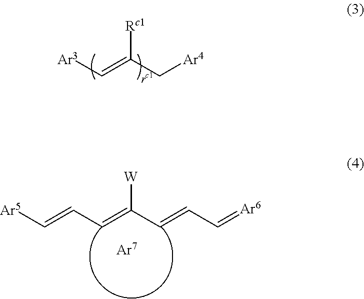

In Formula (3), Ar³ and Ar⁴ each independently represent a heterocyclic group which may have the specific substituent, and R^{o} represents a hydrogen atom or a substituent. However, at least one of Ar³ or Ar⁴ represents a heterocyclic group having a specific substituent. The specific substituent included in the heterocyclic group represented by Ar³ and Ar⁴ is as described above.

Examples of a heterocyclic ring constituting the heterocyclic group include an indolenine ring, a benzoindolenine ring, an imidazole ring, a benzimidazole ring, a naphthimidazole ring, thiazole ring, a benzothiazole ring, a naphthothiazole ring, a thiazoline ring, an oxazole ring, a benzoxazole ring, a naphthoxazole ring, an oxazoline ring, a selenazole ring, a benzoselenazole ring, a naphthoselenazole ring, and a quinoline ring; and an indolenine ring, a benzoindolenine ring, a benzothiazole ring, or a naphthothiazole ring is preferable. The specific substituent may be substituted on a heteroatom in the heterocyclic ring, or may be substituted on a carbon atom in the heterocyclic ring.

The heterocyclic group may have only one specific substituent, or may have a plurality of (for example, 2 or 3) specific substituents.

r^{c1} represents an integer of 1 to 7, and is preferably an integer of 3 to 5.

R^{c1} represents a hydrogen atom or a substituent. The type of the substituent is not particularly limited, examples thereof include known substituents, and an alkyl group which may have a substituent, an aryl group which may have a substituent, or a heteroaryl group which may have a substituent is preferable.

Examples of the substituent which may be included in the alkyl group, the aryl group, or the heteroaryl group include an alkyl group, an alkenyl group, an alkynyl group, an aryl group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfamoyl group, a carbamoyl group, an alkylthio group, an arylthio group, an aromatic heterocyclicthio group, a ureide group, a halogen atom, a cyano group, a nitro group, a heterocyclic group (for example, a heteroaryl group), a silyl group, and a group obtained by combining these groups (hereinafter, these groups are also collectively referred to as “substituent W”). The above-described substituent may be further substituted with the substituent W.

In Formula (4), Ar⁵ and Ar⁶ each independently represent a heterocyclic group which may have the specific substituent; Ar⁷ represents a cyclic skeleton having 5 to 7 carbon atoms; and W represents a hydrogen atom, a halogen atom, a methyl group, a phenyl group which may have a substituent, a benzyl group which may have a substituent, a pyridyl group, a morpholyl group, a piperidyl group, a phenylamino group which may have a substituent, a phenoxy group which may have a substituent, an alkylthio group which may have a substituent, or a phenylthio group which may have a substituent. However, at least one of Ar⁵ or Ar⁶ represents a heterocyclic group having a specific substituent.

The specific substituent included in the heterocyclic group represented by Ar⁵ and Ar⁶ is as described above.

Examples of a heterocyclic ring constituting the heterocyclic group include an indolenine ring, a benzoindolenine ring, an imidazole ring, a benzimidazole ring, a naphthimidazole ring, thiazole ring, a benzothiazole ring, a naphthothiazole ring, a thiazoline ring, an oxazole ring, a benzoxazole ring, a naphthoxazole ring, an oxazoline ring, a selenazole ring, a benzoselenazole ring, a naphthoselenazole ring, and a quinoline ring; and an indolenine ring, a benzoindolenine ring, a benzothiazole ring, or a naphthothiazole ring is preferable.

Examples of the substituent which may be included in the phenyl group, the benzyl group, the phenylamino group, the phenoxy group, the alkylthio group, or the phenylthio group represented by W include the groups exemplified by the substituent W described above, a hydrophilic group, and the specific substituent.

The number of carbon atoms in the alkylthio group represented by W is not particularly limited, but is preferably 1 to 5 and more preferably 1 to 3.

The compound represented by Formula (4) is preferably an intramolecular salt type having a cation and an anion in one molecule or an intermolecular salt type; and examples of the intermolecular salt type include a halide salt, perchlorate, fluoroantimonate, fluorophosphate, fluoroborate, trifluoromethanesulfonate, bis(trifluoromethane)sulfonic acid imide salt, and organic salts of naphthalene sulfonic acid or the like.

Specific examples thereof include indocyanine green and water-soluble coloring agents described in JP1988-033477A (JP-S63-033477A).

The compound represented by Formula (4) is preferably a compound represented by Formula (4-1).

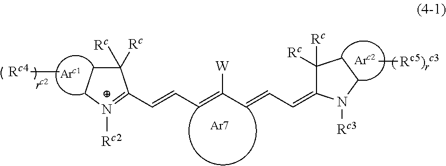

In Formula (4-1), R^{c2} to R^{c5} each independently a hydrogen atom or a substituent; any one of R^{c2} to R^{c5} represents a substituent having —SO₃⁻ (for example, an alkyl group having —SO₃⁻; the number of carbon atoms in the alkyl group is preferably 1 to 10), a substituent having —COO⁻ (for example, an alkyl group having —COO⁻; the number of carbon atoms in the alkyl group is preferably 1 to 10), —SO₃⁻, or —COO⁻; Ar^{c1} and Ar^{c2} each independently represent an aromatic hydrocarbon ring (for example, a benzene ring or a naphthalene ring); Ar⁷ represents a cyclic skeleton having 5 to 7 carbon atoms; W represents a hydrogen atom, a halogen atom, a methyl group, a phenyl group which may have a substituent, a benzyl group which may have a substituent, a pyridyl group, a morpholyl group, a piperidyl group, a phenylamino group which may have a substituent, a phenoxy group which may have a substituent, an alkylthio group which may have a substituent, or a phenylthio group which may have a substituent; r^{c2} represents an integer of 1 to 3; and r^{c3} represents an integer of 1 to 3.

Examples of the substituent represented by R^{c2} to R^{c5} include the groups exemplified by the substituent W, and the specific substituent.

R^{c}'s each independently represent a hydrogen atom or a substituent. Examples of the substituent represented by R^{c} include the groups exemplified by the substituent W, and an alkyl group is preferable. The number of carbon atoms in the above-described alkyl group is preferably 1 to 5.

Examples of the substituent which may be included in the phenyl group, the benzyl group, the phenylamino group, the phenoxy group, the alkylthio group, or the phenylthio group represented by W include the groups exemplified by the substituent W, and the specific substituent.

Examples of the compound represented by Formula (3) and the compound represented by Formula (4) include compound examples 3 to 6.

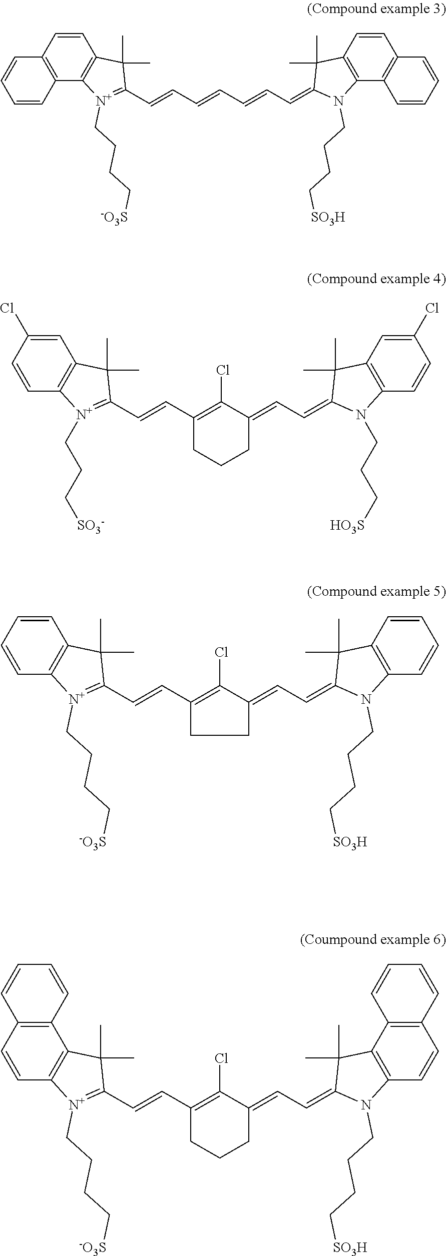

The squarylium-based coloring agent having a hydrophilic group is a coloring agent having a squaric acid in a central skeleton.

The squarylium-based coloring agent having a hydrophilic group is preferably a compound represented by Formula (5).

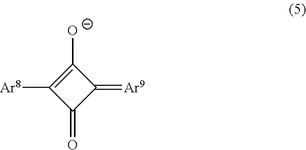

In Formula (5), Ar⁸ and Ar⁹ each independently represent a heterocyclic group which may have the specific substituent. Ar⁸ and Ar⁹ are preferably the above-described heterocyclic ring represented by Ar⁶.

The compound represented by Formula (5) also has an intramolecular salt type or an intermolecular salt type, and has a salt form same as the cyanine-based colorant.

The squarylium-based colorant having a hydrophilic group is preferably a compound represented by Formula (5-1) or a compound represented by Formula (5-2).

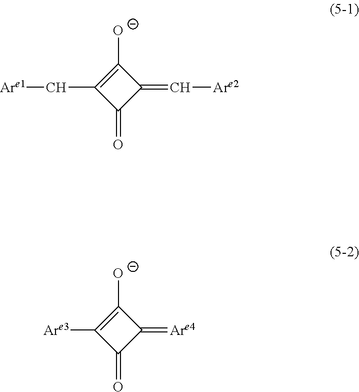

In Formula (5-1), Ar^{c1} represents a heterocyclic group which may have the specific substituent. Ar^{c4} represents a heterocyclic group including N⁺, which may have the specific substituent. However, at least one of the heterocyclic group represented by Ar^{c1} or the heterocyclic group represented by Ar^{c2} has the specific substituent.

In Formula (5-2), Ar^{c3} represents a heterocyclic group which may have the specific substituent. Ar^{c4} represents a heterocyclic group including N⁺, which may have the specific substituent. However, at least one of the heterocyclic group represented by Ar^{c3} or the heterocyclic group represented by Ar^{c4} has the specific substituent.

The azo-based coloring agent is a coloring agent absorbing a visible light region and is mainly used for a water-soluble ink. However, there also commercially available azo-based coloring agents which can absorb light in the infrared region because their absorption band has been widened.

Examples of the azo-based coloring agent include C. I. Acid Black 2 (manufactured by Orient Chemical Industries Co., Ltd.) and C. I. Direct Black 19 (manufactured by Sigma-Aldrich Corporation) described in JP5979728B.

In addition, the azo-based coloring agent can also form a complex with a metal atom. Examples of the complex including the azo-based coloring agent include a compound represented by Formula (6).

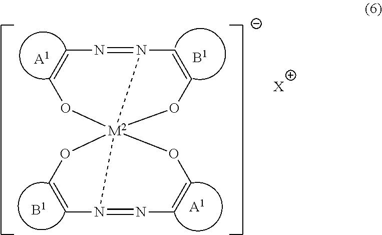

In Formula (6), M² represents a metal atom, and examples thereof include cobalt and nickel.

A¹ and B¹ each independently represent an aromatic ring which may have the specific substituent. However, any one of A¹ or B¹ represents an aromatic ring having a specific substituent.

Examples of the aromatic ring include a benzene ring and a naphthalene ring.

X⁺ represents a cation. Examples of the cation include H⁺, an alkali metal cation, and an ammonium cation.

Examples of the complex including the azo-based coloring agent include coloring agents described in JP1984-011385A (JP-S59-011385A).

Examples of the metal complex-based coloring agent include a compound represented by Formula (7) and a compound represented by Formula (8).

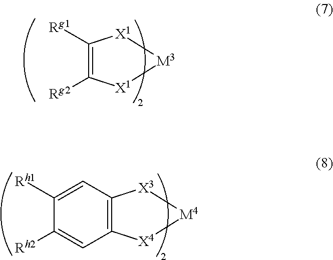

In Formula (7), M³ represents a metal atom, R^{g1} and R^{g2} each independently represent a hydrogen atom or a substituent, at least one of R^{g1} or R^{g2} represents a specific substituent, and X¹ and X² each independently represent an oxygen atom, a sulfur atom, or —NR^{g3}—. R^{g3} represents a hydrogen atom, an alkyl group, or an aryl group.

Examples of the metal atom represented by M³ include Pd, Ni, Co, and Cu, and Ni is preferable.

The type of the substituent represented by R^{g1} and R^{g2} is not particularly limited, and examples thereof include the groups exemplified by the substituent W described above and the specific substituent. At least one of R^{g1} or R^{g2} may represent the specific substituent or both R^{g1} and R^{g2} may represent the specific substituent.

In Formula (8), M⁴ represents a metal atom, R^{h1} and R^{h2} each independently represent a hydrogen atom or a substituent, at least one of R^{h1} or R^{h2} represents a specific substituent, and X³ and X⁴ each independently represent an oxygen atom, a sulfur atom, or —NR^{h3}—. R^{h3} represents a hydrogen atom, an alkyl group, or an aryl group.

Examples of the metal atom represented by M⁴ include Pd, Ni, Co, and Cu, and Ni is preferable.

The type of the substituent represented by R^{h1} and R^{h2} is not particularly limited, and examples thereof include the groups exemplified by the substituent W described above and the specific substituent. At least one of R^{h1} or R^{h2} may represent the specific substituent or both R^{h1} and R^{h2} may represent the specific substituent.

Examples of the boron complex-based coloring agent having a hydrophilic group include a compound represented by Formula (9).

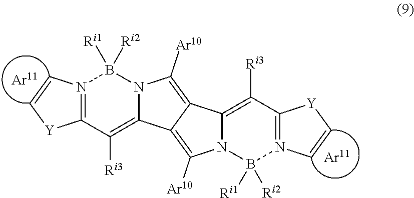

In Formula (9), R^{il} and Rⁱ² each independently represent a hydrogen atom, an alkyl group, or a phenyl group; Rⁱ³'s each independently represent an electron withdrawing group; Ar¹⁰'s each independently represent an aryl group which may have a substituent; at least one of two Ar¹⁰'s represents an aryl group having a substituent; Ar¹¹'s each independently represent an aromatic hydrocarbon ring or an aromatic heterocyclic ring, which may have a substituent; and Y represents a sulfur atom or an oxygen atom.

The electron withdrawing group represented by Rⁱ³ is not particularly limited, and represents a substituent having a positive Hammett's sigma para value (σp value); and examples thereof include a cyano group, an acyl group, an alkyloxycarbonyl group, an aryloxycarbonyl group, a sulfamoyl group, a sulfinyl group, and a heterocyclic group.

These electron withdrawing groups may be further substituted.

The Hammett's substituent constant σp value will be described. The Hammett's rule is an empirical rule advocated by L. P. Hammett in 1935 so as to quantitatively discuss the effect of substituent on the reaction or equilibrium of benzene derivatives and its propriety is widely admitted at present. Substituent constants obtained by the Hammett's rule are an σp value and an am value, and these values can be found in many general books. For example, it is specifically described in Chem. Rev., 1991, vol. 91, pages 165 to 195. In the present invention, a substituent having the Hammett's substituent constant σp value of 0.20 or more is preferable as the electron withdrawing group. The σp value is preferably 0.25 or more, more preferably 0.30 or more, and still more preferably 0.35 or more. The upper limit thereof is not particularly limited, but is preferably 0.80 or less.

Specific examples thereof include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), and an arylsulfonyl group (—SO₂Ph: 0.68).

The aryl group which may have a specific substituent represented by Ar¹⁰ is preferably a phenyl group which may have a specific substituent.

The definition of the specific substituent is as described above, and the aspect of q=1 is preferable.

The aromatic hydrocarbon ring in the aromatic hydrocarbon ring which may have a substituent, represented by Ar¹¹, is preferably a benzene ring or a naphthalene ring. Examples of the substituent which may be included in the aromatic hydrocarbon ring and the aromatic heterocyclic ring represented by Ar¹¹ include the groups exemplified by the substituent W described above and the specific substituent.

The diimonium-based coloring agent having a hydrophilic group is a coloring agent having absorption on a relatively long wavelength side (950 to 1100 nm) even in a near-infrared region, and is preferably a compound represented by Formula (10).

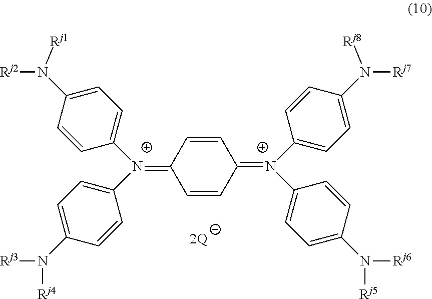

In Formula (10), R^{j1} to R^{j8} each independently an alkyl group which may have a substituent or an aromatic ring group which may have a substituent, and at least one of R^{j1} to R^{j8} represents an alkyl group having a specific substituent or an aromatic ring group having a specific substituent.

Q⁻ represents an anion, and examples thereof include halide ions, perchlorate ions, fluoroantimonate ions, fluorophosphate ions, fluoroborate ions, trifluoromethanesulfonate ions, bis(trifluoromethane)sulfonic acid imide ions, and naphthalene sulfonic acid ions.

The oxonol-based coloring agent having a hydrophilic group is preferably a compound represented by Formula (11).

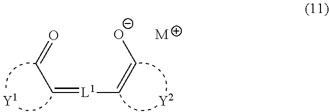

In Formula (11), Y¹ and Y² each independently represent an aliphatic ring or a non-metal atomic group forming a heterocyclic ring; M⁺ represents a proton, a monovalent alkali metal cation, or an organic cation; L¹ represents a methylene chain consisting of 5 or 7 methine groups, in which a methine group at a center of the methylene chain has a substituent represented by Formula (A) of *-S^{A}-T^{A}; in Formula (A), S^{A} represents a single bond, an alkylene group, an alkenylene group, an alkynylene group, —O—, —S—, —NR^{L1}—, —C(═O)—, —C(═O)O—, —C(═O)NR^{L1}—, —S(═O)₂—, —OR^{L2}—, or a group formed by a combination thereof; R^{L1} represents a hydrogen atom, a halogen atom, an alkyl group, an aryl group, or a heteroaryl group; R^{L2} represents an alkylene group, an arylene group, or a divalent heterocyclic group; T^{A} represents a halogen atom, an alkyl group, a cycloalkyl group, an aryl group, a heteroaryl group, a cyano group, a hydroxy group, a formyl group, a carboxy group, an amino group, a thiol group, a sulfo group, a phosphoryl group, a boryl group, a vinyl group, an ethynyl group, a trialkylsilyl group, or a trialkoxysilyl group; S^{A} represents a single bond or an alkylene group; in a case where T^{A} represents an alkyl group, the total number of carbon atoms included in S^{A} and T^{A} is 3 or more; and * represents a bonding site with the methine group at the center of the methylene chain.

The oxonol-based colorant having a hydrophilic group is more preferably a compound represented by Formula (12).

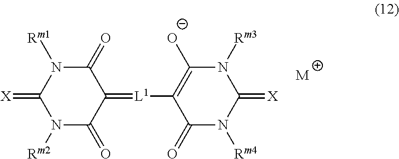

In Formula (12), M⁺ and L¹ are the same as M⁺ and L¹ in Formula (11).

R^{m1}, R^{m2}, R^{m3}, and R^{m4} each independently represent a hydrogen atom, an alkyl group, an aryl group, or a heteroaryl group, and X's each independently represent an oxygen atom, a sulfur atom, or a selenium atom.

The oxonol-based colorant having a hydrophilic group is still more preferably a compound represented by Formula (13).

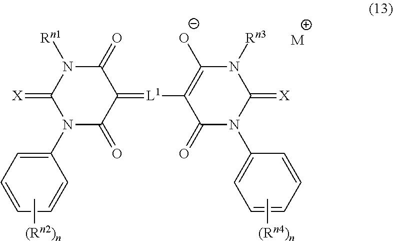

In Formula (13), M⁺, L¹, and X are the same as M⁺, L¹, and X in Formula (11).

Rⁿ¹ and Rⁿ³ each independently represent a hydrogen atom, an alkyl group, an aryl group, or a heteroaryl group; Rⁿ² and R⁴ each independently represent an alkyl group, a halogen atom, an alkenyl group, an aryl group, a heteroaryl group, a nitro group, a cyano group, —OR^{L3}, —C(═O)R^{L3}, —C(═O)OR^{L3}, —OC(═O)R^{L3}, —N(R^{L3})₂, —NHC(═O)R^{L3}, —C(═O)N(R^{L3})₂, —NHC(═O)OR^{L3}, —OC(═O)N(R^{L3})₂, —NHC(═O)N(R^{L3})₂, —SR^{L3}—, —S(═O)₂R^{L3}—, —S(═O)₂OR^{L3}, —NHS(═O)₂R^{L3}, or —S(═O)₂N(R^{L3})₂: R^{L3}'s each independently represent a hydrogen atom, an alkyl group, an alkenyl group, an aryl group, or a heteroaryl group; and n's each independently represent an integer of 1 to 5.

In the present specification, the “rylene” refers to a compound having a molecular structure of a naphthalene unit bonded to a peri-position. Depending on the number of naphthalene units, the “rylene” may be, for example, perylene (n=2), terylene (n=3), quaterrylene (n=4), or higher rylene.

The rylene-based coloring agent is preferably a compound represented by Formula (14), a compound represented by Formula (15), or a compound represented by Formula (16).

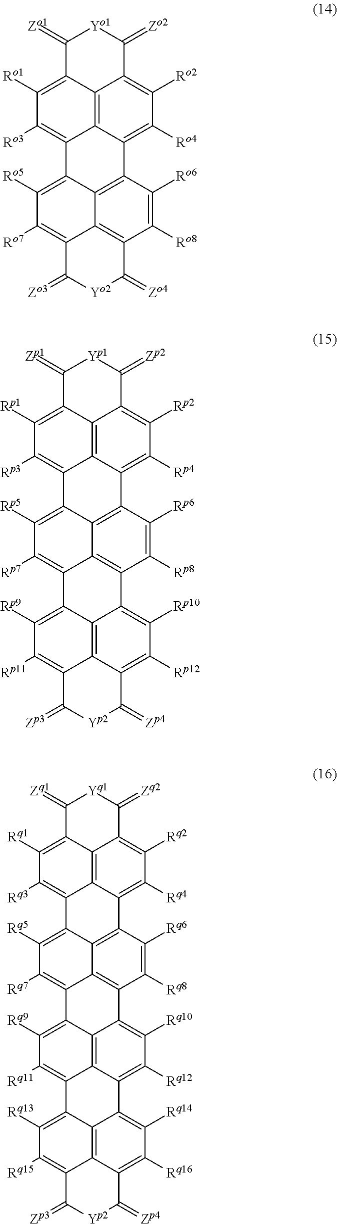

In Formula (14), Y^{o1} and Y^{o2} each independently represent an oxygen atom or NR^{w1}; R^{w1} represents a hydrogen atom or a substituent; Z^{o1} to Z^{o4} each independently represent an oxygen atom or NR^{W2}; R^{w2} represents a hydrogen atom or a substituent; R^{o1} to R^{o8} each independently represent a hydrogen atom or a substituent; and at least one of R^{o1} to R^{o8} represents a specific substituent, at least one of Y^{o1} or Y^{o2} is NR^{W1} in which R^{w1} is the specific substituent, or at least one of Z^{o1} to Z^{o4} is NR^{W2} in which R²² is the specific substituent. R^{W1} and R^{W2} may be bonded to each other to form a ring which may have a substituent. In a case where the ring to be formed has two or more substituents, the substituents may be bonded to each other to form a ring (for example, an aromatic ring).

In Formula (15), Y^{p1} and Y^{p2} each independently represent an oxygen atom or NR^{w3}; R^{w3} represents a hydrogen atom or a substituent; Z^{p1} to Z^{p4} each independently represent an oxygen atom or NR^{W4}; R^{w4} represents a hydrogen atom or a substituent; R^{p1} to R^{p12} each independently represent a hydrogen atom or a substituent; and at least one of R^{p1} to R^{p12} represents a specific substituent, at least one of Y^{p1} or Y^{p2} is NR^{W3} in which R^{w3} is the specific substituent, or at least one of Z^{p1} to Z^{p4} is NR^{W4} in which R^{w4} is the specific substituent. R^{W3} and R^{W4} may be bonded to each other to form a ring which may have a substituent. In a case where the ring to be formed has two or more substituents, the substituents may be bonded to each other to form a ring (for example, an aromatic ring).

In Formula (16), Y^{q1} and Y^{q2} each independently represent an oxygen atom or NR^{w5}; R^{w5} represents a hydrogen atom or a substituent; Z^{q1} to Z^{q4} each independently represent an oxygen atom or NR^{W6}; R^{w6} represents a hydrogen atom or a substituent; R^{q1} to R¹⁶ each independently represent a hydrogen atom or a substituent; and at least one of R^{q1} to R^{q16}, or R^{z} represents a specific substituent, at least one of Y^{q1} or Y^{q2} is NR^{W5} in which R^{w5} is the specific substituent, or at least one of Z^{q1} to Z^{q4} is NR^{W6} in which R^{w6} is the specific substituent. R^{W5} and R^{W6} may be bonded to each other to form a ring which may have a substituent. In a case where the ring to be formed has two or more substituents, the substituents may be bonded to each other to form a ring (for example, an aromatic ring).

It is preferable that the specific dichroic coloring agent constitutes a J-aggregate. That is, it is preferable that the polarizing plate includes a J compound composed of the specific dichroic coloring agent.

The J-aggregate is an aggregate of coloring agents. More specifically, the J-aggregate refers to a state in which coloring agent molecules are associated with each other with a constant deviation angle (slip angle). The J-aggregate has an absorption band with a narrow half-width and a high absorption light absorption coefficient on a long wavelength side as compared with a case of a single coloring agent molecule in a solution state. This sharpened absorption band is referred to as a J-band. The J-band is described in detail in literature (for example, Photographic Science and Engineering Vol 18, No 323-335 (1974)). Whether or not it is a J-aggregate can be easily determined by measuring its maximal absorption wavelength.

An absorption peak of the J-band is shifted to a long wavelength side with respect to the absorption peak of a single coloring agent molecule, and a difference between the wavelength of the absorption peak of the J-band and the wavelength of the absorption peak of the single coloring agent molecule is preferably 10 to 300 nm and more preferably 30 to 250 nm.

In a case where the specific dichroic coloring agent forms the J-aggregate, it is preferable that the maximal absorption wavelength of the J-aggregate is located in the wavelength range of 800 to 1,500 nm.

The specific dichroic coloring agent may be used singly or in a combination of two or more kinds thereof.

A content of the dichroic coloring agent in the polarizing plate is not particularly limited, but from the viewpoint that absorption characteristics of the polarizing plate are more excellent, it is preferably 1% to 20% by mass, more preferably 1% to 18% by mass, and still more preferably 3% to 15% by mass with respect to the total mass of the polarizing plate.

### (Other Components)

The polarizing plate according to the embodiment of the present invention may contain a component other than the above-described dichroic coloring agent.

Examples of other components include a liquid crystal compound. The liquid crystal compound can be classified into a low-molecular-weight type and a high-molecular-weight type.

The liquid crystal compound may be a lyotropic liquid crystal compound or a thermotropic liquid crystal compound. Among these, from the viewpoint of ease of manufacturing the polarizing plate according to the embodiment of the present invention, a lyotropic liquid crystal compound is preferable.

The polarizing plate according to the embodiment of the present invention may contain a non-colorable lyotropic liquid crystal compound. As will be described later, the polarizing plate can be easily manufactured by using a composition containing the specific dichroic coloring agent and the non-colorable lyotropic liquid crystal compound.

The non-coloring property means that no absorption is exhibited in the visible light region. More specifically, the non-coloring property means that the absorbance in a visible light range (wavelength of 400 to 700 nm) is 0.1 or less in a case of measuring the ultraviolet-visible absorption spectrum of the solution in which the lyotropic liquid crystal compound is dissolved at a concentration such that the absorbance at the maximal absorption wavelength in an ultraviolet light range (230 to 400 nm) is 1.0.

The lyotropic liquid crystal compound is a compound exhibiting lyotropic liquid crystallinity. The lyotropic liquid crystallinity refers to a property of causing a phase transition between an isotropic phase and a liquid crystal phase by changing a concentration in a solution state of being dissolved in a solvent.

From the viewpoint that it is easy to control the expression of liquid crystallinity, the lyotropic liquid crystal compound is preferably water-soluble. The water-soluble lyotropic liquid crystal compound represents a lyotropic liquid crystal compound which is dissolved in water in an amount of 1% by mass or more, and a lyotropic liquid crystal compound which is dissolved in water in an amount of 5% by mass or more is preferable.

A type of the lyotropic liquid crystal compound is not particularly limited as long as the above-described polarizing plate can be formed. Among these, from the viewpoint of being able to form the polarizing plate with good productivity, the non-colorable lyotropic liquid crystal compound is preferably a non-colorable lyotropic liquid crystalline rod-like compound (hereinafter, also simply referred to as “rod-like compound”) or a non-colorable lyotropic liquid crystalline plate-like compound (hereinafter, also simply referred to as “plate-like compound”). As the non-colorable lyotropic liquid crystal compound, only the rod-like compound may be used, only the plate-like compound may be used, or the rod-like compound and the plate-like compound may be used in combination.

Hereinafter, the rod-like compound and the plate-like compound will be described in detail.

### (Rod-Like Compound)

The polarizing plate may contain a rod-like compound. The rod-like compound tends to be aligned in a predetermined direction.

The rod-like compound exhibits lyotropic liquid crystallinity.

From the viewpoint that it is easy to control the expression of liquid crystallinity, the rod-like compound is preferably water-soluble. The water-soluble rod-like compound represents a rod-like compound which is dissolved in water in an amount of 1% by mass or more, and a rod-like compound which is dissolved in water in an amount of 5% by mass or more is preferable.

The rod-like compound refers to a compound having a structure in which ring structures (an aromatic ring, a non-aromatic ring, and the like) are one-dimensionally connected through a single bond or a divalent linking group, and refers to a group of compounds which have a property of aligning major axes thereof to each other in a solvent.

The rod-like compound preferably has a maximal absorption wavelength in a wavelength range of 300 nm or less. That is, the rod-like compound preferably has a maximal absorption peak in a wavelength range of 300 nm or less.

The maximal absorption wavelength of the above-described rod-like compound means a wavelength at which absorbance is the maximal value in an absorption spectrum of the rod-like compound (measurement range: wavelength range of 230 to 400 nm). In a case where there are a plurality of maximal values in the absorbance of the absorption spectrum of the rod-like compound, a wavelength on the longest wavelength side in the measurement range is selected.

Among these, from the viewpoint that the aligning properties of the specific dichroic coloring agent in the polarizing plate are more excellent, the rod-like compound preferably has a maximal absorption wavelength in a range of 230 to 300 nm, and more preferably has a maximal absorption wavelength in a range of 250 to 290 nm. As described above, the maximal absorption wavelength of the rod-like compound is preferably located at 250 nm or more.

A measuring method of the above-described maximal absorption wavelength is as follows.

The rod-like compound (5 to 50 mg) is dissolved in pure water (1,000 mL), and using a spectrophotometer (MPC-3100 (manufactured by Shimadzu Corporation)), an absorption spectrum of the obtained solution is measured.

From the viewpoint that the aligning properties of the specific dichroic coloring agent in the polarizing plate are more excellent, the rod-like compound preferably has a hydrophilic group.

The rod-like compound may have only one hydrophilic group, or may have a plurality of hydrophilic groups.

The definition of the hydrophilic group is the same as the definition of the hydrophilic group included in the specific dichroic coloring agent, and a suitable aspect thereof is also the same.

As the rod-like compound, from the viewpoint that the aligning properties of the specific dichroic coloring agent in the polarizing plate are more excellent, a polymer having a repeating unit represented by Formula (X) is preferable.

R^{x1}-L^{x1}-R^{x2}-L^{x2} (X)

R^{x1} represents a divalent aromatic ring group having a substituent including a hydrophilic group, a divalent non-aromatic ring group having a substituent including a hydrophilic group, or a group represented by Formula (X1). In Formula (X1), * represents a bonding position.

*—R^{x3}-L^{x3}-R^{x4}—* Formula (X1)

R^{x3} and R^{x4} each independently represent a divalent aromatic ring group which may have a substituent including a hydrophilic group or a divalent non-aromatic ring group which may have a substituent including a hydrophilic group, in which at least one of R^{x3} or R^{x4} represents a divalent aromatic ring group having a substituent including a hydrophilic group or a divalent non-aromatic ring group having a substituent including a hydrophilic group.

L^{x3} represents a single bond, —O—, —S—, an alkylene group, an alkenylene group, or an alkynylene group.

The divalent aromatic ring group and the divalent non-aromatic ring group represented by R^{x1} have a substituent including a hydrophilic group.

Examples of the hydrophilic group included in the substituent including a hydrophilic group include the groups exemplified by the hydrophilic group included in the specific dichroic coloring agent described above, and an acid group or a salt thereof is preferable.

The substituent including a hydrophilic group is preferably a group represented by Formula (H). In Formula (H), * represents a bonding position.

R^{H}-L^{H}-* Formula (H)

R^{H} represents a hydrophilic group. The definition of the hydrophilic group is as described above.

L^{H} represents a single bond or a divalent linking group. The divalent linking group is not particularly limited, and examples thereof include a divalent hydrocarbon group (for example, a divalent aliphatic hydrocarbon group such as an alkylene group having 1 to 10 carbon atoms, an alkenylene group having 1 to 10 carbon atoms, or an alkynylene group having 1 to 10 carbon atoms, and a divalent aromatic hydrocarbon ring group such as an arylene group); a divalent heterocyclic group, —O—, —S—, —SO₂—, —NH—, —CO—, and a group obtained by combining these groups (for example, —CO—O—, —O-divalent hydrocarbon group-, —(O-divalent hydrocarbon group)ₘ-O— (m represents an integer of 1 or more), -divalent hydrocarbon group-O—CO—, and the like).

The number of substituents including a hydrophilic group in the divalent aromatic ring group is not particularly limited, but from the viewpoint that the aligning properties of the specific dichroic coloring agent in the polarizing plate are more excellent, it is preferably 1 to 3 and more preferably 1.

The number of substituents including a hydrophilic group in the divalent non-aromatic ring group is not particularly limited, but from the viewpoint that the aligning properties of the specific dichroic coloring agent in the polarizing plate are more excellent, it is preferably 1 to 3 and more preferably 1.

An aromatic ring constituting the divalent aromatic ring group having the substituent including a hydrophilic group, represented by R^{x1}, may have a monocyclic structure or a polycyclic structure.

Examples of the aromatic ring constituting the above-described divalent aromatic ring group include an aromatic hydrocarbon ring and an aromatic heterocyclic ring. That is, examples of R^{x1} include a divalent aromatic hydrocarbon ring group having the substituent including a hydrophilic group and a divalent aromatic heterocyclic group having the substituent including a hydrophilic group.

Examples of the aromatic hydrocarbon ring include a benzene ring and a naphthalene ring.

Examples of a structure of only the divalent aromatic hydrocarbon ring group portion of the divalent aromatic hydrocarbon ring group having the substituent including a hydrophilic group include the following group. * represents a bonding position.

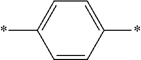 [SMILES: *c1ccc(*)cc1]

Examples of the aromatic heterocyclic ring include a pyridine ring, a thiophene ring, a pyrimidine ring, a thiazole ring, a furan ring, a pyrrole ring, an imidazole ring, and an indole ring.

Examples of a structure of only the divalent aromatic heterocyclic group portion of the divalent aromatic heterocyclic group having the substituent including a hydrophilic group include the following group. * represents a bonding position.

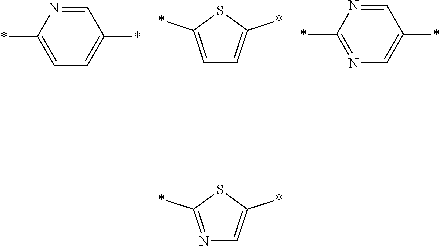

A non-aromatic ring constituting the divalent non-aromatic ring group having the substituent including a hydrophilic group, represented by R^{x1}, may have a monocyclic structure or a polycyclic structure.

Examples of the non-aromatic ring constituting the above-described divalent non-aromatic ring group include an aliphatic ring and a non-aromatic heterocyclic ring, and from the viewpoint that the aligning properties of the specific dichroic coloring agent in the polarizing plate are more excellent, an aliphatic ring is preferable, cycloalkane is more preferable, and cyclohexane is still more preferable. That is, examples of R^{x1} include a divalent aliphatic ring group having a substituent including a hydrophilic group and a divalent non-aromatic heterocyclic group having a substituent including a hydrophilic group, and a divalent cycloalkylene group having a substituent including a hydrophilic group is preferable.

The aliphatic ring may be a saturated aliphatic ring or an unsaturated aliphatic ring.

Examples of a structure of only the divalent aliphatic ring group portion of the divalent aliphatic ring group having the substituent including a hydrophilic group include the following groups. * represents a bonding position.

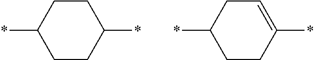

A heteroatom included in the non-aromatic heterocyclic ring is not particularly limited; and examples thereof include an oxygen atom, a nitrogen atom, and a sulfur atom.

The number of heteroatoms included in the non-aromatic heterocyclic ring is not particularly limited, and examples thereof include 1 to 3.

Examples of a structure of only the divalent non-aromatic heterocyclic group portion of the divalent non-aromatic heterocyclic group having the substituent including a hydrophilic group include the following group. * represents a bonding position.

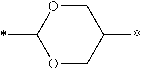 [SMILES: *C1COC(*)OC1]

The divalent aromatic ring group having a substituent including a hydrophilic group and the divalent non-aromatic ring group having a substituent including a hydrophilic group, represented by R^{x1}, may have a substituent other than the substituent including a hydrophilic group.

The substituent is not particularly limited, and examples thereof include an alkyl group, an alkenyl group, an alkynyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, an alkylthio group, an arylthio group, an aromatic heterocyclic thio group, a ureido group, a halogen atom, a cyano group, a hydrazino group, a heterocyclic group (for example, a heteroaryl group), a silyl group, and a group obtained by combining these groups. The above-described substituent may be further substituted with a substituent.

R^{x3} and R^{x4} each independently represent a divalent aromatic ring group which may have a substituent including a hydrophilic group or a divalent non-aromatic ring group which may have a substituent including a hydrophilic group, in which at least one of R^{x3} or R^{x4} represents a divalent aromatic ring group having a substituent including a hydrophilic group or a divalent non-aromatic ring group having a substituent including a hydrophilic group.

The definition of the substituent including a hydrophilic group, which may be included in the divalent aromatic ring group represented by R^{x3} and R^{x4}, is as described above. In addition, the definition of the aromatic ring constituting the divalent aromatic ring group, which may have the substituent including a hydrophilic group and is represented by R^{x3} and R^{x4}, is the same as the definition of the aromatic ring constituting the above-described divalent aromatic ring group having the substituent including a hydrophilic group, represented by R^{x1}.

The definition of the substituent including a hydrophilic group, which may be included in the divalent non-aromatic ring group represented by R^{x3} and R^{x4}, is as described above.

In addition, the definition of the non-aromatic ring constituting the divalent non-aromatic ring group, which may have the substituent including a hydrophilic group and is represented by R^{x3} and R^{x4}, is the same as the definition of the non-aromatic ring constituting the above-described divalent non-aromatic ring group having the substituent including a hydrophilic group, represented by R^{x1}.

At least one of R^{x3} or R^{x4} represent a divalent aromatic ring group having the substituent including a hydrophilic group or a divalent non-aromatic ring group having the substituent including a hydrophilic group, in which both R^{x3} and R^{x4} may represent the divalent aromatic ring group having the substituent including a hydrophilic group or the divalent non-aromatic ring group having the substituent including a hydrophilic group.

The definition of the divalent aromatic ring group having the substituent including a hydrophilic group, represented by R^{x3} and R^{x4}, has the same meaning as the above-described divalent aromatic ring group having the substituent including a hydrophilic group, represented by R^{x1}.

In addition, the definition of the divalent non-aromatic ring group having the substituent including a hydrophilic group, represented by R^{x3} and R^{x4}, has the same meaning as the above-described divalent non-aromatic ring group having the substituent including a hydrophilic group, represented by R^{x1}.

L^{x3} represents a single bond, —O—, —S—, an alkylene group, an alkenylene group, or an alkynylene group.

The number of carbon atoms in the alkylene group is not particularly limited, but from the viewpoint that the aligning properties of the specific dichroic coloring agent in the polarizing plate are more excellent, it is preferably 1 to 3 and more preferably 1.

The number of carbon atoms in the alkenylene group and in the alkynylene group is not particularly limited, but from the viewpoint that the alignment of the specific dichroic coloring agent in the polarizing plate is more excellent, it is preferably 2 to 5 and more preferably 2 to 4.

R^{x2} represents a divalent non-aromatic ring group, a divalent aromatic ring group, or a group represented by Formula (X2). In Formula (X2), * represents a bonding position.

*—Z^{x1}-Z^{x2}-* Formula (X2)

Z^{x1} and Z^{x2} each independently represent a divalent non-aromatic ring group or a divalent aromatic ring group. * represents a bonding position.

A non-aromatic ring constituting the divalent non-aromatic ring group represented by R^{x2} may have a monocyclic structure or a polycyclic structure.

Examples of the non-aromatic ring constituting the above-described divalent non-aromatic ring group include an aliphatic ring and a non-aromatic heterocyclic ring, and from the viewpoint that the aligning properties of the specific dichroic coloring agent in the polarizing plate are more excellent, an aliphatic ring is preferable, cycloalkane is more preferable, and cyclohexane is still more preferable. That is, examples of R^{x2} include a divalent aliphatic ring group and a divalent non-aromatic heterocyclic group, and a divalent cycloalkylene group is preferable.

The aliphatic ring may be a saturated aliphatic ring or an unsaturated aliphatic ring.

Examples of the divalent aliphatic ring group include the following groups. * represents a bonding position.

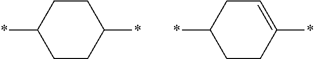

A heteroatom included in the non-aromatic heterocyclic ring is not particularly limited; and examples thereof include an oxygen atom, a nitrogen atom, and a sulfur atom.

The number of heteroatoms included in the non-aromatic heterocyclic ring is not particularly limited, and examples thereof include 1 to 3.

Examples of the divalent non-aromatic heterocyclic group include the following group. * represents a bonding position.

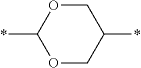 [SMILES: *C1COC(*)OC1]

The divalent non-aromatic ring group may have a substituent. The type of the substituent is not particularly limited; and examples thereof include the groups exemplified by the substituent other than the substituent including a hydrophilic group, which may be included in the divalent aromatic ring group having the substituent including a hydrophilic group or the divalent non-aromatic ring group having the substituent including a hydrophilic group, represented by R^{x1}.

An aromatic ring constituting the divalent aromatic ring group represented by R^{x2} may have a monocyclic structure or a polycyclic structure.

Examples of the aromatic ring include an aromatic hydrocarbon ring and an aromatic heterocyclic ring.

Examples of the aromatic hydrocarbon ring include a benzene ring and a naphthalene ring.

Examples of the aromatic heterocyclic ring include a pyridine ring, a thiophene ring, a pyrimidine ring, a thiazole ring, a furan ring, a pyrrole ring, an imidazole ring, and an indole ring.

The divalent aromatic ring group may have a substituent. The type of the substituent is not particularly limited; and examples thereof include the groups exemplified by the substituent other than the substituent including a hydrophilic group, which may be included in the divalent aromatic ring group having the substituent including a hydrophilic group or the divalent non-aromatic ring group having the substituent including a hydrophilic group, represented by R^{x1}.

Z^{x1} and Z^{x2} each independently represent a divalent non-aromatic ring group or a divalent aromatic ring group.

The definition of the divalent non-aromatic ring group represented by Z^{x1} and Z^{x2} and the definition of the divalent aromatic ring group are the same as the definition of the divalent non-aromatic ring group represented by R^{x2} and the definition of the divalent aromatic ring group described above.

L^{x1} and L^{x2} each independently represent —CONH—, —COO—, —O—, or —S—. Among these, from the viewpoint that the aligning properties of the specific dichroic coloring agent are more excellent, —CONH— is preferable.

The repeating unit represented by Formula (X) is preferably a repeating unit represented by Formula (X4).

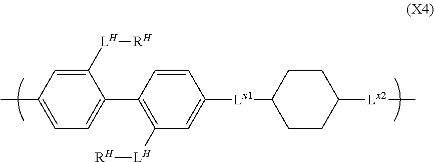

The definition of each group in Formula (X4) is as described above.

A content of the repeating unit represented by Formula (X) included in the polymer having the repeating unit represented by Formula (X) is not particularly limited, but is preferably 60% by mole or more and more preferably 80% by mole or more with respect to all repeating units in the polymer. The upper limit thereof is, for example, 100% by mole.

A molecular weight of the polymer having the repeating unit represented by Formula (X) is not particularly limited, and the number of repeating units represented by Formula (X) in the polymer is preferably 2 or more, more preferably 10 to 100,000, and still more preferably 100 to 10,000.

In addition, a number-average molecular weight of the polymer having the repeating unit represented by Formula (X) is not particularly limited, but is preferably 5,000 to 50,000 and more preferably 10,000 to 30,000.

In addition, a molecular weight distribution of the polymer having the repeating unit represented by Formula (X) is not particularly limited, but is preferably 1.0 to 12.0 and more preferably 1.0 to 7.0.

Here, the number-average molecular weight and the molecular weight distribution in the present invention are values measured by a gel permeation chromatography (GPC) method.
Solvent (eluent): 20 mM phosphate (pH: 7.0)/acetonitrile=4/1
Device name: TOSOH HLC-8220GPC
Column: using three columns of G6000PWxL, 4500PWxL, and G2500pWwL manufactured by Tosoh Corporation connected with each other
Column temperature: 40° C.
Sample concentration: 2 mg/mL
Flow rate: 1 mL/min
Calibration curve: calibration curve using 8 samples up to polystyrene sulfonic acid (PSS) Mp=891, 4,200, 10,200, 29,500, 78,400, 152,000, 258,000, and 462,000

### (Plate-Like Compound)

The polarizing plate may contain a plate-like compound.

The “plate-like compound” refers to a compound having a structure in which aromatic rings (an aromatic hydrocarbon ring, an aromatic heterocyclic ring, and the like) are spread two-dimensionally through a single bond or an appropriate linking group, and refers to a group of compounds which have a property of forming column-like associate by associating planes in the compound in a solvent.

The plate-like compound exhibits lyotropic liquid crystallinity.

From the viewpoint that it is easy to control the expression of liquid crystallinity, the plate-like compound is preferably water-soluble. The water-soluble plate-like compound represents a plate-like compound which is dissolved in water in an amount of 1% by mass or more, and a plate-like compound which is dissolved in water in an amount of 5% by mass or more is preferable.

The plate-like compound preferably has a maximal absorption wavelength in a wavelength range of more than 300 nm. That is, the plate-like compound preferably has a maximal absorption peak in a wavelength range of more than 300 nm.

The maximal absorption wavelength of the above-described plate-like compound means a wavelength at which absorbance is the maximal value in an absorption spectrum of the plate-like compound (measurement range: wavelength range of 230 to 400 nm). In a case where there are a plurality of maximal values in the absorbance of the absorption spectrum of the plate-like compound, a wavelength on the longest wavelength side in the measurement range is selected.

Among these, the plate-like compound preferably has a maximal absorption wavelength in a range of 320 to 400 nm, and more preferably has a maximal absorption wavelength in a range of 330 to 360 nm.

A measuring method of the above-described maximal absorption wavelength is as follows.

The plate-like compound (0.01 to 0.05 mmol) is dissolved in pure water (1,000 ml), and using a spectrophotometer (MPC-3100 (manufactured by Shimadzu Corporation)), an absorption spectrum of the obtained solution is measured.

From the viewpoint that the aligning properties of the specific dichroic coloring agent in the polarizing plate are more excellent, the plate-like compound preferably has a hydrophilic group.

The definition of the hydrophilic group is the same as the definition of the hydrophilic group which may be included in the rod-like compound.

The plate-like compound may have only one hydrophilic group, or may have a plurality of hydrophilic groups. In a case where the plate-like compound has a plurality of hydrophilic groups, the number thereof is preferably 2 to 4 and more preferably 2.

From the viewpoint that the aligning properties of the specific dichroic coloring agent in the polarizing plate are more excellent, the plate-like compound is preferably a compound represented by Formula (Y).

R^{y2}-L^{y3}-L^{y1}-R^{y1}-L^{y2}-L^{y4}-R^{y3} Formula(Y)

R^{y1} represents a divalent monocyclic group or a divalent fused polycyclic group.

Examples of a ring included in the divalent monocyclic group include a monocyclic hydrocarbon ring and a monocyclic heterocyclic ring. The monocyclic hydrocarbon ring may be a monocyclic aromatic hydrocarbon ring or a monocyclic non-aromatic hydrocarbon ring. The monocyclic heterocyclic ring may be a monocyclic aromatic heterocyclic ring or a monocyclic non-aromatic heterocyclic ring.

From the viewpoint that the aligning properties of the specific dichroic coloring agent in the polarizing plate are more excellent, the divalent monocyclic group is preferably a divalent monocyclic aromatic hydrocarbon ring group or a divalent monocyclic aromatic heterocyclic group.

The number of ring structures included in the divalent fused polycyclic group is not particularly limited, but from the viewpoint that the aligning properties of the specific dichroic coloring agent in the polarizing plate are more excellent, it is preferably 3 to 10, more preferably 3 to 6, and still more preferably 3 or 4.

Examples of the ring included in the divalent fused polycyclic group include a hydrocarbon ring and a heterocyclic ring. The hydrocarbon ring may be an aromatic hydrocarbon ring or a non-aromatic hydrocarbon ring. The heterocyclic ring may be an aromatic heterocyclic ring or a non-aromatic heterocyclic ring.

From the viewpoint that the aligning properties of the dichroic coloring agent are more excellent, the divalent fused polycyclic group is preferably composed of an aromatic hydrocarbon ring and a heterocyclic ring. The divalent fused polycyclic group is preferably a conjugated linking group. That is, the divalent fused polycyclic group is preferably a conjugated divalent fused polycyclic group.

Examples of the ring constituting the divalent fused polycyclic group include dibenzothiophene-S,S-dioxide (a ring represented by Formula (Y2)), dinaphtho[2,3-b:2′,3′-d]furan (a ring represented by Formula (Y3)), 12H-benzo“b”phenoxazine (a ring represented by Formula (Y4)), dibenzo[b,i]oxantrene (a ring represented by Formula (Y5)), benzo[b]naphtho[2′, 3′: 5,6]dioxino[2,3-i]oxantrene (a ring represented by Formula (Y6)), acenaphtho[1,2-b]benzo[g]quinoxaline (a ring represented by Formula (Y7)), 9H-acenaphtho[1,2-b]imidazo[4,5-g]quinoxaline (a ring represented by Formula (Y8)), dibenzo[b,def]chrysene-7,14-dione (a ring represented by Formula (Y9)), and acetonaphthoquinoxaline (a ring represented by Formula (Y10)).

That is, examples of the divalent fused polycyclic group include divalent groups formed by removing two hydrogen atoms from rings represented by Formulae (Y2) to (Y10).

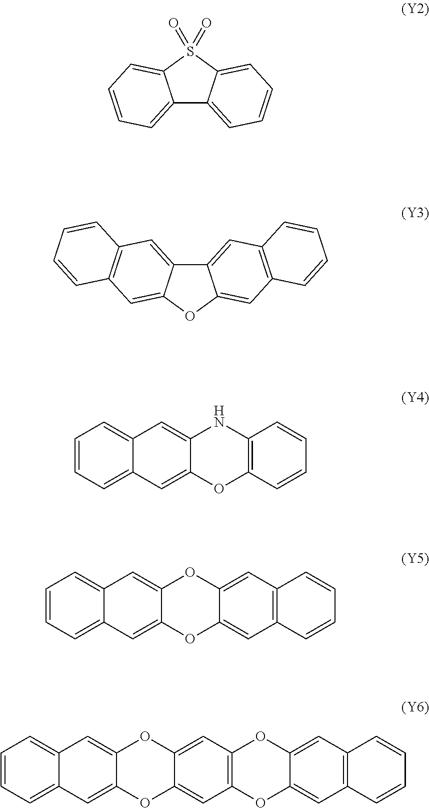 [SMILES: O=S1(=O)c2ccccc2-c2ccccc21 ; c1ccc2cc3c(cc2c1)oc1cc2ccccc2cc13 ; c1ccc2c(c1)Nc1cc3ccccc3cc1O2 ; c1ccc2cc3c(cc2c1)Oc1cc2ccccc2cc1O3 ; c1ccc2cc3oc4cc5oc6cc7ccccc7cc6oc5cc4oc3cc2c1]

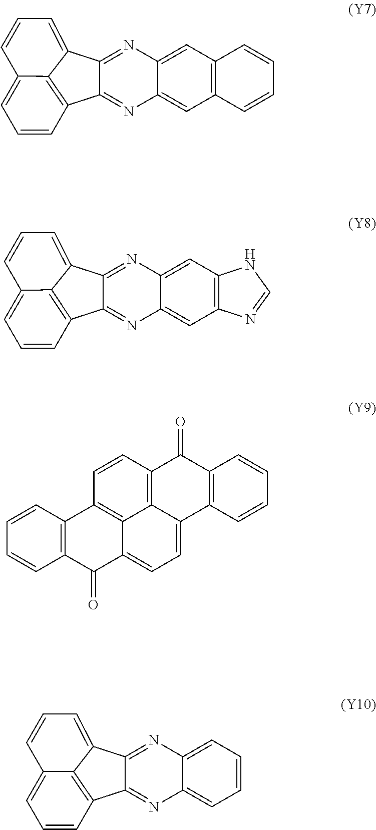 [SMILES: c1ccc2cc3nc4c(nc3cc2c1)-c1cccc2cccc-4c12 ; c1cc2c3c(cccc3c1)-c1nc3cc4[nH]cnc4cc3nc1-2 ; O=C1c2ccccc2-c2ccc3c4c(ccc1c24)-c1ccccc1C3=O ; c1cc2c3c(cccc3c1)-c1nc3ccccc3nc1-2]

The divalent monocyclic group and the divalent fused polycyclic group may have a substituent. The type of the substituent is not particularly limited; and examples thereof include the groups exemplified by the substituent other than the substituent including a hydrophilic group, which are included in the divalent aromatic ring group having the substituent including a hydrophilic group or the divalent non-aromatic ring group having the substituent including a hydrophilic group, represented by R^{x1}.

R^{y2} and R^{y3} each independently represent a hydrogen atom or a hydrophilic group, and at least one of R^{y2} or R^{y3} represents a hydrophilic group. It is preferable that both R^{y2} and R^{y3} represent a hydrophilic group.

The definition of the hydrophilic group represented by R^{y2} and R^{y3} is as described above.

L^{y1} and L^{y2} each independently represent a single bond, a divalent aromatic ring group, or a group represented by Formula (Y1). However, in a case where R^{y1} is a divalent monocyclic group, both L^{y1} and L^{y2} represent a divalent aromatic ring group or a group represented by Formula (Y1). In Formula (Y1), * represents a bonding position.

*—R^{y5}—(R^{y5})ₙ—* Formula(Y1)

R^{y4} and R^{y5} each independently represent a divalent aromatic ring group.

n represents 1 or 2.

An aromatic ring constituting the divalent aromatic ring group represented by L^{y1} and L^{y2} may have a monocyclic structure or a polycyclic structure.

Examples of the aromatic ring constituting the above-described divalent aromatic ring group include an aromatic hydrocarbon ring and an aromatic heterocyclic ring. That is, examples of the divalent aromatic ring group represented by L^{y1} and L^{y2} include a divalent aromatic hydrocarbon ring group and a divalent aromatic heterocyclic group.

Examples of the aromatic hydrocarbon ring include a benzene ring and a naphthalene ring.

Examples of the divalent aromatic hydrocarbon ring group include the following group. * represents a bonding position.

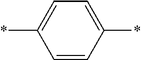 [SMILES: *c1ccc(*)cc1]

Examples of the aromatic heterocyclic ring include a pyridine ring, a thiophene ring, a pyrimidine ring, a thiazole ring, a furan ring, a pyrrole ring, an imidazole ring, and an indole ring.

Examples of the divalent aromatic heterocyclic group include the following groups. * represents a bonding position.

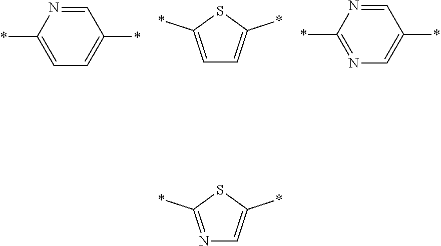

The definition of the divalent aromatic ring group represented by R^{y4} and R^{y5} is also the same as the divalent aromatic ring group represented by L^{y1} and L^{y2}.

L^{y3} and L^{y4} each independently represent a single bond, —O—, —S—, an alkylene group, an alkenylene group, an alkynylene group, or a group obtained by combining these groups.

Examples of the above-described group obtained by combining these groups include —O-alkylene group- and —S-alkylene group-.

The number of carbon atoms in the alkylene group is not particularly limited, but from the viewpoint that the aligning properties of the specific dichroic coloring agent in the polarizing plate are more excellent, it is preferably 1 to 3 and more preferably 1.

The number of carbon atoms in the alkenylene group and in the alkynylene group is not particularly limited, but from the viewpoint that the aligning properties of the specific dichroic coloring agent in the polarizing plate is more excellent, it is preferably 2 to 5 and more preferably 2 to 4.

In a case where the polarizing plate contains the liquid crystal compound, a content of the liquid crystal compound in the polarizing plate is not particularly limited, but is preferably 60% to 99% by mass and more preferably 80% to 97% by mass with respect to the total mass of the polarizing plate.

### (Salt)

The polarizing plate may contain salt.

In a case where the plate-like compound has an acid group or a salt thereof, by containing a salt in the polarizing plate, planes in the plate-like compound are more likely to associate with each other, and column-like aggregates are likely to be formed.

The above-described salt does not include the above-described rod-like compound and the above-described plate-like compound. That is, the above-described salt is a compound different from the above-described rod-like compound and the above-described plate-like compound.

The salt is not particularly limited, and may be an inorganic salt or an organic salt, but from the viewpoint that the aligning properties of the specific dichroic coloring agent in the polarizing plate are more excellent, an inorganic salt is preferable. Examples of the inorganic salt include an alkali metal salt, an alkaline earth metal salt, and a transition metal salt, and from the viewpoint that the aligning properties of the specific dichroic coloring agent in the polarizing plate are more excellent, an alkali metal salt is preferable.

The alkali metal salt is a salt in which a cation is an alkali metal ion, and the alkali metal salt is preferably lithium ion or sodium ion, and more preferably lithium ion. That is, as the salt, a lithium salt or a sodium salt is preferable, and a lithium salt is more preferable.

Examples of the alkali metal salt include hydroxides of an alkali metal, such as lithium hydroxide, sodium hydroxide, and potassium hydroxide; carbonates of an alkali metal, such as lithium carbonate, sodium carbonate, and potassium carbonate; and bicarbonates of an alkali metal, such as lithium bicarbonate, sodium bicarbonate, and potassium bicarbonate.

In addition to the above, the alkali metal salt may be, for example, a phosphate or a chloride.

Examples of an anion of the above-described salt include a hydroxide ion, a carbonate ion, a chloride ion, a sulfate ion, a nitrate ion, a phosphate ion, a borate ion, a tetrafluoroborate ion, a hexafluorophosphate ion, a perchlorate ion, a toluenesulfonate ion, an oxalate ion, a formate ion, a trifluoroacetate ion, a trifluoromethanesulfonate ion, a bis(fluoromethanesulfonyl)imide ion, a bis(pentafluoroethanesulfonyl)imide ion, and a bis(trifluoromethanesulfonyl)imide ion.

In a case where the plate-like compound has a salt of an acid group, it is preferable that the cation in the salt of an acid group and the cation in the salt used are of the same type.

The polarizing plate according to the embodiment of the present invention may contain a binder polymer in addition to the above-described liquid crystal compound.

As the binder polymer, a known polymer can be used, and examples thereof include a polycarbonate resin, a polyolefin-based resin (particularly, a cycloolefin polymer), a cellulose-based resin, and an acrylic resin.

As will be described later, in a case where the polarizing plate is a stretching film, the binder polymer can be used for producing the stretching film.

### <Method for Manufacturing Polarizing Plate>

A method for manufacturing the polarizing plate is not particularly limited as long as the polarizing plate having the above-described characteristics can be manufactured.

Among these, from the viewpoint of more excellent productivity, a method for manufacturing a polarizing plate, including the following step 1 and step 2, is preferable.
Step 1: step of subjecting a composition containing a dichroic coloring agent having a hydrophilic group and a solvent to a pulverization treatment
Step 2: step of applying the composition obtained in the step 1 and aligning the dichroic coloring agent in the applied composition to form a polarizing plate

Hereinafter, the procedures of steps 1 and 2 will be described in detail.

### (Step 1)

The step 1 is a step of subjecting a composition containing a dichroic coloring agent having a hydrophilic group (the specific dichroic coloring agent) and a solvent (hereinafter, also simply referred to as “specific composition”) to a pulverization treatment. By performing this step, dispersibility of the specific dichroic coloring agent in the specific composition is improved, and as a result, a polarizing plate in which aligning properties of the specific dichroic coloring agent are more excellent is obtained. In particular, in a case where the specific composition contains particles composed of the specific dichroic coloring agent, an average particle diameter of the particles is smaller, and a polarizing plate in which the aligning properties of the specific dichroic coloring agent are more excellent is obtained.

Hereinafter, first, the specific composition to be used will be described in detail, and then the procedure of the step will be described in detail.

The specific composition contains the specific dichroic coloring agent. The specific dichroic coloring agent is as described above.

In the specific composition, the specific dichroic coloring agent is often dispersed in a form of particles. That is, in many cases, the specific composition contains particles composed of the specific dichroic coloring agent.

The specific composition may contain only one kind of the specific dichroic coloring agent, or may contain two or more kinds of the specific dichroic coloring agents.

A content of the specific dichroic coloring agent in the specific composition is not particularly limited, but is preferably 1% to 30% by mass and more preferably 3% to 15% by mass with respect to the total mass of components in the composition excluding a solvent (corresponding to the total solid content in the composition).

The specific composition contains a solvent.

The type of the solvent is not particularly limited, but an aqueous medium is preferable.

The aqueous medium is water or a mixed solution of water and a water-soluble organic solvent.

The water-soluble organic solvent is a solvent having a solubility in water of 5% by mass or more at 20° C. Examples of the water-soluble organic solvent include alcohol compounds, ketone compounds, ether compounds, amide compounds, nitrile compounds, and sulfone compounds.

Examples of the alcohol compound include ethanol, isopropanol, n-butanol, t-butanol, isobutanol, 1-methoxy-2-propanol, diacetone alcohol, diethylene glycol, ethylene glycol, dipropylene glycol, propylene glycol, and glycerin.

Examples of the ketone compound include acetone, methyl ethyl ketone, diethyl ketone, and methyl isobutyl ketone.

Examples of the ether compound include dibutyl ether, tetrahydrofuran, dioxane, dipropylene glycol monomethyl ether, tripropylene glycol monomethyl ether, and polyoxypropylene glyceryl ether.

Examples of the amide compound include dimethylformamide and diethylformamide.

Examples of the nitrile compound include acetonitrile.

Examples of the sulfone compound include dimethyl sulfoxide, dimethyl sulfone, and sulfolane.

The above-described solvent is preferably water.

A concentration of solid contents of the specific composition is not particularly limited, but from the viewpoint that the aligning properties of the dichroic coloring agent are more excellent, it is preferably 1% to 50% by mass and more preferably 3% to 30% by mass with respect to the total mass of the composition.

The specific composition may contain a component other than the specific dichroic coloring agent and the solvent described above.

Examples of other components include a non-colorable lyotropic liquid crystal compound, a salt, a polymerizable compound, a polymerization initiator, a wavelength dispersion control agent, an optical properties modifier, a surfactant, an adhesion improver, a slipping agent, an alignment control agent, and an ultraviolet absorber.

As described above, the specific composition may contain a non-colorable lyotropic liquid crystal compound. The description of the non-colorable lyotropic liquid crystal compound is as described above.

In a case where the specific composition contains the non-colorable lyotropic liquid crystal compound, a content of the non-colorable lyotropic liquid crystal compound in the specific composition is not particularly limited, but is preferably 60% to 99% by mass and more preferably 80% to 97% by mass with respect to the total solid content in the composition.

The total solid content means components capable of forming the polarizing plate, excluding a solvent. In a case where the property of the above-described component is in a liquid state, it is counted as the solid content.

In a case where the specific composition contains both the rod-like compound and the plate-like compound, a content of the rod-like compound with respect to the total mass of the rod-like compound and the plate-like compound is not particularly limited, but from the viewpoint that the alignment of the specific dichroic coloring agent in the polarizing plate is more excellent, it is preferably more than 50% by mass and more preferably 55% by mass or more. The upper limit thereof is not particularly limited, but is preferably 90% by mass or less and more preferably 80% by mass or less.

The specific composition may contain one kind of the rod-like compound, or may contain two or more kinds of the rod-like compounds.

The specific composition may contain one kind of the plate-like compound, or may contain two or more kinds of the plate-like compounds.

As described above, the specific composition may contain a salt. The description of the salt is as described above.

In a case where the specific composition contains the rod-like compound, the plate-like compound, and the salt, a content of the salt is not particularly limited, but a ratio W determined by Expression (W) is preferably 0.25 to 1.75, more preferably 0.50 to 1.50, and still more preferably 0.75 to 1.15.

$$Ratio W = \frac{( C 1 + C 2 + C 3 ) - ( A 1 + A 2 )}{A 2} \qquad ( W )$$

In Expression (W), C1 represents a molar amount of a cation included in the salt of an acid group, which is contained in the rod-like compound. In a case where the rod-like compound does not have the salt of an acid group, C1 is 0.

C2 represents a molar amount of a cation included in the salt of an acid group, which is contained in the plate-like compound. In a case where the plate-like compound does not have the salt of an acid group, C2 is 0.

C3 represents a molar amount of a cation included in the salt.

A1 represents a total molar amount of the acid group or the salt thereof, contained in the rod-like compound. In a case where the rod-like compound contains both the acid group and the salt of an acid group, the above-described total molar amount represents a total molar amount of the acid group and the salt of an acid group. In a case where the rod-like compound has only one of the acid group or the salt of an acid group, the molar amount of one not contained is 0.

A2 represents a total molar amount of the acid group or the salt thereof, contained in the plate-like compound. In a case where the plate-like compound contains both the acid group and the salt of an acid group, the above-described total molar amount represents a total molar amount of the acid group and the salt of an acid group. In a case where the plate-like compound has only one of the acid group or the salt of an acid group, the molar amount of one not contained is 0.

For example, with regard to a composition containing a rod-like compound having a SO₃Li group, a plate-like compound having a SO₃Li group, and LiOH, in a case where a molar amount of the SO₃Li group included in the rod-like compound is 5 mmol, a molar amount of the SO₃Li group included in the plate-like compound is 8 mmol, and a molar amount of LiOH is 8 mmol, it is calculated that a molar amount of the cation included in the salt of an acid group, contained in the rod-like compound, is 5 mmol, a molar amount of the cation included in the salt of an acid group, contained in the plate-like compound, is 8 mmol, and a molar amount of the cation included in LiOH is 8 mmol, and the ratio W is calculated as {(5+8+8)−(5+8)}/8=1.

In a case where the above-described rod-like compound is a rod-like compound having a SO₃H group and the molar amount of the SO₃H group included in the rod-like compound is 5 mmol, the ratio W is calculated as {(8+8)−(5+8)}/8=0.375.

The above-described ratio W represents an amount of cation derived from an excess salt in the composition with respect to the acid group or the salt thereof in the plate-like compound. That is, the ratio W represents a ratio of the amount of excess cations which does not form a salt with the acid group contained in the rod-like compound and plate-like compound in the composition to the acid group or the salt thereof contained in the plate-like compound. In a case where the specific composition contains a predetermined amount of cations with respect to the acid group or the salt thereof contained in the plate-like compound, it is easily assumed that the polarizing plate has a predetermined structure in the plate-like compound, and the alignment degree of the dichroic coloring agent is more excellent.

In a case where the specific composition contains the salt, a mass ratio of the content of the salt to the content of the plate-like compound in the specific composition is not particularly limited, but is preferably 0.010 to 0.200 and more preferably 0.025 to 0.150.

The specific composition is preferably a lyotropic liquid crystalline composition.

Here, the lyotropic liquid crystalline composition is a composition having a property of causing a phase transition between an isotropic phase and a liquid crystal phase by changing a temperature or a concentration in a solution state. That is, the specific composition is a composition capable of exhibiting lyotropic liquid crystallinity by adjusting the concentration of each compound, or the like in a solution state containing various components such as the specific dichroic coloring agent and the solvent. Even in a case where the specific composition contains an excess solvent and does not exhibit lyotropic liquid crystallinity in that state, the specific composition corresponds to the above-described lyotropic liquid crystalline composition in a case where the lyotropic liquid crystallinity is exhibited upon changes in the concentration, such as a case where the lyotropic liquid crystallinity is exhibited in a drying step after application of the specific composition.

As will be described later, in a case where an alignment film is disposed on a support, the lyotropic liquid crystallinity is expressed in the drying process after the application of the specific composition, thereby inducing the alignment of the compound and making it possible to form the polarizing plate.

### (Procedure of Step 1)

In the step 1, the specific composition is subjected to a pulverization treatment.

As the pulverization treatment, a known pulverization treatment can be used. Examples of a method of the pulverization treatment include a method of applying mechanical energy, such as compression, squeezing, impact, shearing, rubbing, and cavitation.

The pulverization treatment may be a wet pulverization treatment or a dry pulverization treatment. Specific examples of the pulverization treatment include treatments using a beads mill, a sand mill, a roll mill, a ball mill, a paint shaker, a microfluidizer, an impeller mill, a sand grinder, a flow jet mixer, an ultrasonic treatment, or the like.

As the pulverization treatment, from the viewpoint that aligning properties of the specific dichroic coloring agent in the polarizing plate are more excellent, a mechanical milling treatment or an ultrasonic treatment is preferable, and a mechanical milling treatment is more preferable.

The mechanical milling treatment is not particularly limited as long as it is a method of milling while applying mechanical energy, and examples thereof include treatments using a ball mill, a vibration mill, a turbo mill, a mechanofusion, and a disc mill.

In a case where the specific composition contains particles composed of the specific dichroic coloring agent, by performing the pulverization treatment, the particles are pulverized to obtain smaller particles (miniaturized particles).

Conditions of the pulverization treatment are not particularly limited, and optimal conditions are appropriately selected depending on the types of the specific dichroic coloring agent and the solvent used.

For example, in a case where the mechanical milling treatment (particularly, a ball mill treatment) is adopted as the pulverization treatment, a material of pulverizing balls (media) used in the ball milling is not particularly limited, and examples thereof include agate, silicon nitride, zirconia, alumina, and an iron-based alloy. From the viewpoint that aligning properties of the specific dichroic coloring agent in the polarizing plate are more excellent, zirconia is preferable.

An average diameter of the pulverizing balls is not particularly limited, but from viewpoint that aligning properties of the specific dichroic coloring agent in the polarizing plate are more excellent, it is preferably 0.1 to 10 mm and more preferably 1 to 5. The above-described average particle diameter is a value obtained by measuring diameters of any 50 pulverizing balls and arithmetically averaging the diameters. In a case where the pulverizing ball is not spherical, a major axis is taken as the diameter.

A rotation speed during the ball milling is not particularly limited, but from viewpoint that aligning properties of the specific dichroic coloring agent in the polarizing plate are more excellent, it is preferably 100 to 700 rpm and more preferably 250 to 550 rpm.

A treatment time of the ball milling is not particularly limited, but from viewpoint that aligning properties of the specific dichroic coloring agent in the polarizing plate are more excellent, it is preferably 5 to 240 minutes and more preferably 10 to 180 minutes.

The atmosphere during the ball milling may be an atmosphere of atmospheric air, or may be an atmosphere of an inert gas (for example, argon, helium, or nitrogen).

It is preferable that, by the pulverization treatment, the average particle diameter of the particles composed of the specific dichroic coloring agent, contained in the specific composition, is miniaturized to be 1/30 to ½ times.

That is, the particles composed of the specific dichroic coloring agent may be contained in the specific composition after the pulverization treatment, and the average particle diameter of the particles is not particularly limited, but from the viewpoint that the alignment degree of the dichroic substance is more excellent, it is preferably 10 to 1,000 nm, more preferably 10 to 500 nm, and still more preferably 10 to 200 nm.

The average particle diameter of the particles is a volume average particle size (MV) obtained by a dynamic light scattering method using Nanotrack UPA-EX manufactured by MicrotracBEL Corp.

As described above, the specific composition subjected to the pulverization treatment may or may not contain a component other than the specific dichroic coloring agent and the solvent, such as a non-colorable lyotropic liquid crystal compound.

In a case where the specific composition subjected to the pulverization treatment does not contain the other components (for example, a non-colorable lyotropic liquid crystal compound), the specific composition obtained after the pulverization treatment may be further mixed with the other components (for example, the non-colorable lyotropic liquid crystal compound), and then the step 2 described below may be performed.

### (Step 2)

The step 2 is a step of applying the composition (specific composition) obtained in the step 1 and aligning the above-described dichroic coloring agent (specific dichroic coloring agent) in the applied composition to form the polarizing plate. By performing this step, the polarizing plate according to the embodiment of the present invention, having light absorption anisotropy, is manufactured.

A method of applying the specific composition obtained in the step 1 is not particularly limited, and usually, the specific composition is applied onto a support.

A support to be used is a member having a function as a base material for applying the composition. The support may be a so-called temporary support.

Examples of the support (temporary support) include a plastic substrate and a glass substrate. Examples of a material constituting the plastic substrate include a polyester resin such as polyethylene terephthalate, a polycarbonate resin, a (meth)acrylic resin, an epoxy resin, a polyurethane resin, a polyamide resin, a polyolefin resin, a cellulose resin, a silicone resin, and polyvinyl alcohol.

A thickness of the support may be approximately 5 to 1,000 μm, preferably 10 to 250 μm and more preferably 15 to 90 μm.

As necessary, an alignment film may be disposed on the support.

The alignment film generally contains a polymer as a main component. The polymer for the alignment film is described in a large number of documents, and a large number of commercially available polymer products are available. The polymer for the alignment film is preferably a polyvinyl alcohol, a polyimide, a derivative thereof, an azo derivative, or a cinnamoyl derivative.

It is preferable that the alignment film is subjected to a known rubbing treatment.

In addition, a photo-alignment film may be used as the alignment film.

A thickness of the alignment film is preferably 0.01 to 10 μm and more preferably 0.01 to 1 μm.

The application method may be, for example, a known method, examples thereof include a curtain coating method, an extrusion coating method, a roll coating method, a dip coating method, a spin coating method, a print coating method, a spray coating method, and a slide coating method.

In addition, in a case where the specific composition is a lyotropic liquid crystalline composition, by adopting a coating method of applying shearing to the composition, such as wire bar coating, it is possible to simultaneously perform two treatments of application and alignment of various compounds. That is, the specific dichroic coloring agent can be aligned by subjecting the composition to a shearing treatment.

In addition, in a case where the specific composition contains the non-colorable lyotropic liquid crystal compound, by continuous application, the non-colorable lyotropic liquid crystal compound may be continuously aligned at the same time as the coating. Examples of the continuous application include a curtain coating method, an extrusion coating method, a roll coating method, and a slide coating method.

A method of aligning the specific dichroic coloring agent in the applied composition is not particularly limited, and a known method is adopted.

For example, in a case where the specific composition contains the non-colorable lyotropic liquid crystal compound, examples thereof include a method of applying shearing as described above.

Examples of another method of aligning the specific dichroic coloring agent in the applied composition include a method of using an alignment film as described above.

An alignment direction can be controlled by subjecting the alignment film to an alignment treatment in advance in a predetermined direction. In particular, the method of using an alignment film is preferable in a case where continuous application is carried out using a roll-like support so that the compound is aligned in a direction oblique to a transport direction.

In the method of using an alignment film, a concentration of the solvent in the specific composition used is not particularly limited, and may be a concentration such that the composition exhibits lyotropic liquid crystallinity, or may be a concentration equal to or lower than the concentration. As described above, in a case where the specific composition is a lyotropic liquid crystalline composition, even in a case where the concentration of the solvent in the specific composition is high (a case where the specific composition itself exhibits an isotropic phase), in the drying process after the application of the specific composition, lyotropic liquid crystallinity is exhibited, which induces alignment of the dichroic coloring agent on the alignment film and makes it possible to form the polarizing plate.

### (Other Steps)

The method for manufacturing the polarizing plate according to the embodiment of the present invention may include steps other than the above-described step 1 and step 2.

As other steps, in a case where the specific composition contains the non-colorable lyotropic liquid crystal compound, it is preferable to further include a step 3 of immobilizing the non-colorable lyotropic liquid crystal compound after the step 2.

A method of fixing an alignment state of the non-colorable lyotropic liquid crystal compound is not particularly limited, and examples thereof include a method of heating and then cooling a coating film as described above.

In addition, in a case where at least one of the rod-like compound, the plate-like compound, or the specific dichroic coloring agent has an acid group or a salt thereof, examples of a method of fixing an alignment state of the lyotropic liquid crystal compound include a method of bringing a solution containing a polyvalent metal ion into contact with the formed polarizing plate. By bringing the solution containing a polyvalent metal ion into contact with the formed polarizing plate, the polyvalent metal ion is supplied into the polarizing plate. The polyvalent metal ion supplied into the polarizing plate serves as a crosslinking point between the acid groups or the salts thereof contained in the rod-like compound, the plate-like compound, and/or the specific dichroic coloring agent, a crosslinking structure is formed in the polarizing plate, and the alignment state of the lyotropic liquid crystal compound is fixed.

The type of the polyvalent metal ion used is not particularly limited, but from the viewpoint that the alignment state of the non-colorable lyotropic liquid crystal compound and/or the specific dichroic coloring agent is easily fixed, an alkaline earth metal ion is preferable, and a calcium ion is more preferable.

In the above, the manufacturing method using the lyotropic liquid crystal compound has been described, but a method other than the above-described method may be used.

Examples of another aspect of the method for manufacturing the polarizing plate according to the embodiment of the present invention include a method of forming a un-stretched film using a composition containing a predetermined dichroic substance and the polymer, and stretching and aligning the obtained un-stretched film to form a polarizing plate which is a stretching film.

Examples of a method of forming the un-stretched film include a method of applying a composition containing a predetermined dichroic substance, a polymer, and a solvent to form the un-stretched film, and a method of forming the un-stretched film by melting and forming a solid content containing the predetermined dichroic substance, and the polymer, without using a solvent.

Examples of the stretching method include known methods such as longitudinal uniaxial stretching, horizontal uniaxial stretching, or a combination thereof such as simultaneous biaxial stretching or sequential biaxial stretching.

The dichroic substance used in the manufacturing of the above-described stretching film are as described above.

Examples of the polymer used in the manufacturing of the above-described stretching film include the above-described binder polymers.

By changing stretching conditions of the stretching film and the material used, various characteristics (for example, the average transmittance and the polarization degree) of the polarizing plate described above can be appropriately adjusted.

### <Applications>

The polarizing plate according to the embodiment of the present invention can be applied to various applications.

In addition, in a case of applying the polarizing plate according to the embodiment of the present invention to various applications, the polarizing plate according to the embodiment of the present invention may be combined with other components. For example, another member may be disposed on one surface or both surfaces of the polarizing plate according to the embodiment of the present invention. In a case where the other members are disposed, it may be disposed through an adhesion Layer such as an adhesive layer and a pressure sensitive adhesive layer.

Examples of the other members include an optically anisotropic film, a hardcoat layer, an antiglare layer, and a protective film.

Examples of the optically anisotropic film include a λ/4 plate and a λ/2 plate.

The λ/4 plate is a plate having a function of converting linearly polarized light having a specific wavelength into circularly polarized light (or circularly polarized light into linearly polarized light). More specifically, the λ/4 plate is a plate in which the in-plane retardation Re at a predetermined wavelength λ nm is λ/4 (or an odd multiple thereof).

An in-plane retardation (Re(550)) of the λ/4 plate at a wavelength of 550 nm may have an error of approximately 25 nm based on an ideal value (137.5 nm), and is, for example, preferably 110 to 160 nm and more preferably 120 to 150 nm.

In addition, the λ/2 plate refers to an optically anisotropic film in which an in-plane retardation Re(λ) at a specific wavelength of λ nm satisfies Re(λ)≈λ/2. The expression may be achieved at any wavelength (for example, 550 nm) in the visible light region. Among these, it is preferable that the in-plane retardation Re(550) at a wavelength of 550 nm satisfies the following relationship.

210 nm≤Re(550)≤300 nm

The polarizing plate according to the embodiment of the present invention is preferably applied to an apparatus in which at least one of a display element or a visible light imaging element, and an infrared light sensing system are combined. More specifically, the apparatus according to the embodiment of the present invention is preferably an apparatus including the above-described polarizing plate according to the embodiment of the present invention, at least one of a display element or a visible light imaging element, and an infrared light receiving section. Both the display device and the visible light imaging element may be included in the above-described apparatus.

The above-described apparatus may further include an infrared light source.

From the viewpoint that the infrared light sensing system functions more favorably, a difference between the above-described λ1 and a maximal wavelength λ2 of an infrared light emitted from the infrared light source is preferably 20 nm or less and more preferably 10 nm or less. The lower limit thereof is not particularly limited, but may be, for example, 0 nm.

The above-described difference between λ1 and λ2 indicates an absolute value of (λ1−λ2).

As described above, in the polarizing plate according to the embodiment of the present invention, since the average transmittance at a wavelength of 400 to 700 nm is 70% or more, even in a case where the polarizing plate is disposed on a display surface side of the display element, a transmittance of visible light emitted from the display element is excellent, so that deterioration in brightness and a tint of a display image of the display element are prevented. In addition, even in a case where the polarizing plate is disposed in front of the visible light imaging element, since the average transmittance of the polarizing plate with respect to visible light is high, favorable imaging performance of the visible light imaging element can be maintained without being affected by the polarizing plate. Furthermore, the polarizing plate according to the embodiment of the present invention exhibits excellent polarization characteristics and transmittance of infrared light, resulting in excellent detection characteristics in the infrared light receiving section included in the infrared light sensing system.

A type of the infrared light sensing system is not particularly limited, and examples thereof include various biological sensing functions (biological authentication system) such as a fingerprint sensor (fingerprint authentication system), a vein authentication system, a blood flow sensor, and an iris authentication sensor.

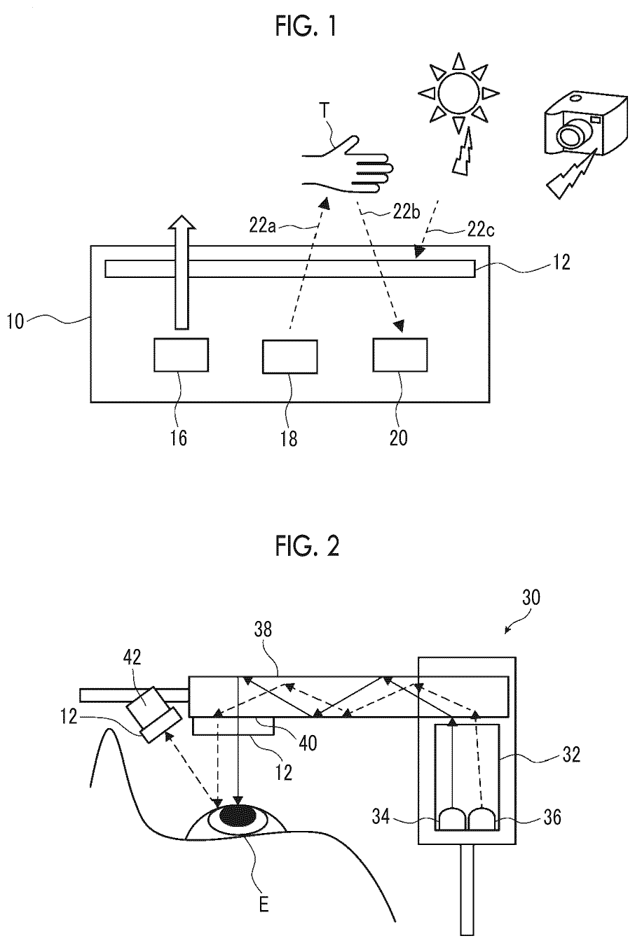

More specifically, in FIG. 1, an image display apparatus including the polarizing plate according to the embodiment of the present invention will be described. An organic electroluminescent (EL) display device 10 shown in FIG. 1 includes a polarizing plate 12 according to the embodiment of the present invention, an organic EL display element 16, an infrared light source 18, and an infrared light receiving section 20. The polarizing plate 12 is disposed on an emission surface side of the organic EL display element 16, and light emitted from the organic EL display element 16 is transmitted through the polarizing plate 12, as indicated by a white arrow. As described above, since the average transmittance of the polarizing plate 12 at a wavelength of 400 to 700 nm is 70% or more, light (image light) emitted from the organic EL display element 16 is unlikely to be absorbed by the polarizing plate 12, so that the deterioration in brightness and the color tint of the display image of the organic EL display element 16 are prevented.

In addition, in the organic EL display device 10, an infrared light 22a is emitted from the infrared light source 18 to a measurement target T, an infrared light 22b reflected by the measurement target T is detected by the infrared light receiving section 20, and the organic EL display device 10 functions as the infrared light sensing system. In the above-described infrared light sensing system, by disposing the polarizing plate 12 on an optical path of the infrared light 22b reflected by the measurement target T, the infrared light 22b transmitted through the polarizing plate 12 is polarized, and thus detection accuracy and acquisition information amount can be improved. In addition, a near-infrared light noise 22c from the outside is incident on the polarizing plate 12 as noise, but since the noise is usually in a polarization state different from non-polarized light or the infrared light 22a emitted from the infrared light source 18, most of these are absorbed by the polarizing plate 12 and do not reach the infrared light receiving section 20. Therefore, the noise can be removed and the detection accuracy can be improved. In the polarizing plate 12 according to the embodiment of the present invention, as described above, since the maximum value of the polarization degree is large and the transmittance T(λ1) at the wavelength λ1 at which the polarization degree is maximized is large, both the detection accuracy and the acquisition information amount can be achieved with a higher balance, while the polarization of the infrared light transmitted through the polarizing plate 12 is increased and the amount of the transmitted light can be secured in a predetermined amount.

Any object can be targeted as the measurement target T. Examples thereof include a part of a living body, such as a hand, a finger, a palm, and a skin of a user; an object of a specific interface device or a surrounding thing, such as a vein pattern, a face, an eyeball, a lip, a hand, and a foot, and a movement or a gesture of these.

As the infrared light receiving section, a photodetector element such as a photodiode and a phototransistor, which is sensitive to infrared light and is not sensitive to visible light, can be applied. The infrared light receiving section is preferably a photodiode or a phototransistor, which has sensitivity only to near-infrared light and does not have sensitivity in a visible light region. As the photodetector element, an organic photodiode (OPD) or an organic phototransistor (OPT) may be adopted.

The infrared light receiving section receives infrared light reflected from a detection target to detect the detection target.

The target detected by the infrared light receiving section is the measurement target T described above; and at least one of a three-dimensional shape of a thing, a surface state of the object, an eye movement of a user, an eye position, a facial expression, a facial shape, a vein pattern, a blood flow, a pulse, a blood oxygen saturation level, a fingerprint, or an iris is preferable.

It is preferable that the infrared light receiving section is provided at a location suitable for these measurement targets.

In the above, the aspect in which the polarizing plate according to the embodiment of the present invention is applied to the organic EL display element has been described, but the polarizing plate according to the embodiment of the present invention may be applied to other image display elements (liquid crystal display elements).

In addition, the polarizing plate according to the embodiment of the present invention can also be applied to other devices other than the image display device, for example, a wearable device such as a head-mounted display, and a mobile display device such as a smartphone and a tablet.

Hereinafter, a head-mounted display including the polarizing plate according to the embodiment of the present invention will be described in detail.

A head-mounted display 30 shown in FIG. 2 includes a display panel 32 and a light guide element 38, and the display panel 32 includes a display element 34 and an infrared light source 36. An image light (solid line) emitted from the display element 34 and infrared light (broken line) emitted from the infrared light source 36 are emitted, through the light guide element 38, from a light emission surface 40 provided in the light guide element 38, transmitted through the polarizing plate 12 according to the embodiment of the present invention, and are incident on an eyeball E of an observer. The infrared light emitted to the eyeball E, reflected is transmitted through the polarizing plate 12 according to the embodiment of the present invention, and then detected by an infrared light receiving section 42. The head-mounted display 30 includes an infrared light sensing system which performs eyeball sensing.

Information obtained by the eyeball sensing is information on eye tracking, personal authentication by the iris, vital information obtained by detecting the surface state of the iris and the retina, and the cornea, blood flow obtained by detecting the blood vessel in the eyeball, blood pressure, heart rate, and analysis information on blood components.

In the above-described head-mounted display 30, since the average transmittance of the polarizing plate 12 at a wavelength of 400 to 700 nm is 70% or more, light (image light) emitted from the display element 34 is unlikely to be absorbed by the polarizing plate 12, so that the deterioration in brightness and the color tint of the display image are prevented.

In addition, since the polarizing plate 12 provided between the light emission surface of the light guide element and the eyeball of the observer has a large maximum value of the polarization degree and a large transmittance T(λ1) at the wavelength λ1 at which the polarization degree is maximized as described above, both the detection accuracy and the acquisition information amount can be achieved with a higher balance, while the effect of noise reducing can be exhibited and a predetermined amount of transmission can be secured.

As the light guide element, in addition to a light guide element which guides light by total internal reflection and is provided with a diffraction element for light incidence and light emission, a light guide element for a head-mounted display, which has been known in the related art, such as a prism mirror which has been subjected to a mirror surface treatment on a surface, can be applied. The light guide element is preferably transparent to infrared light. Examples of a material constituting the light guide element include glass and a resin.

The absorption axis direction of the polarizing plate according to the embodiment of the present invention, which is provided between the light emission surface of the light guide element and the eyeball of the observer, and the absorption axis direction of the polarizing plate according to the embodiment of the present invention, which is provided between the infrared light receiving section and the eyeball of the observer, may be arranged as desired according to the design. As a preferred example, in a case where the cornea of the eyeball of the observer is assumed to be mirror-reflected, polarizing plates are preferably disposed such that they are crossed-nicol disposition (disposition in which the absorption axes of the polarizing plates are orthogonal to each other).

In an iris authentication, an eye tracking method of specifying a position and a size of a pupil, and a sensing system of detecting a state of an inside of an eyeball, such as a retina, a reflection component on a corneal surface becomes noise and becomes an obstacle in measurement. In a case where the absorption axis direction of the polarizing plate provided between the light emission surface of the light guide element and the eyeball of the observer and the absorption axis direction of the polarizing plate provided between the infrared light receiving section and the eyeball of the observer are disposed such that the absorption axis directions of the polarizing plates are in a crossed-nicol disposition with respect to each other in a case where specular reflection is assumed for the eyeball of the observer, reflection from a surface of the cornea having a reflection characteristic close to specular reflection is substantially removed, and reflection in internal tissues such as the iris, the pupil, and the retina is changed in polarization and can be detected by the infrared light receiving section, and a signal can be detected by removing a surface reflection component of the cornea.

As the infrared light receiving section used in the head-mounted display, the infrared light receiving section described in the organic EL display device can be used.

In addition, another preferred example for the noise reducing is that a λ/4 plate which acts as a ¼ wavelength plate at the wavelength is combined with the polarizing plate to form a circularly polarizing plate, whereby the configuration can be made to exclude the reflected component of the corneal surface in the same manner.

In the above, the aspect using the display element has been mainly described, but the polarizing plate according to the embodiment of the present invention can also be suitably applied to a device including a visible light imaging element and an infrared light sensing system.

A configuration of the imaging system including the polarizing plate according to the embodiment of the present invention, the visible light imaging element, and the infrared light receiving section is not particularly limited, but in many cases, the polarizing plate according to the embodiment of the present invention is disposed in front of the visible light imaging element and the infrared light receiving section, visible light transmitted through the polarizing plate is received by the visible light imaging element, and infrared light transmitted through the polarizing plate is received by the infrared light receiving section.

Hereinafter, an imaging system including the polarizing plate according to the embodiment of the present invention will be described in detail.

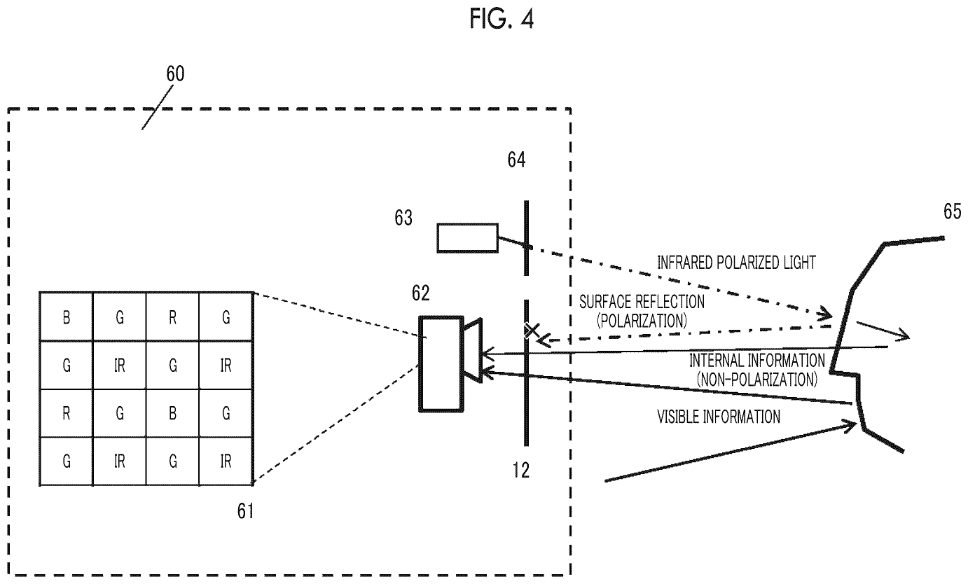

An imaging system 60 shown in FIG. 4 includes a visible imaging element in which an IR color filter and a BGR color filter are arranged in the same imaging element, an IR-RGB camera 62 including an IR-RGB imaging element 61 in which an infrared light receiving section (infrared imaging element) is integrated, the polarizing plate 12 according to the embodiment of the present invention on an incidence side of the camera, and an infrared light source 63 in which an infrared polarizing plate 64 is disposed in an infrared emission direction. In this case, in the polarizing plate 12 according to the embodiment of the present invention and the infrared polarizing plate 64, absorption axes are disposed at a crossed-nicol disposition. Infrared light (one-dot chain line) emitted from the infrared light source 63 and visible light (solid line) incident from the ambient light source are irradiated on an imaging object 65. The visible light is reflected on a surface of the object and is incident on the camera 62 (TR-RGB imaging element 61) without being substantially absorbed with the polarizing plate 12 according to the embodiment of the present invention having a transmittance of 70% or more with respect to the visible light, and the visible image of the object can be obtained. On the other hand, the light reflected from the infrared light, for example, in a case where the object is a living body, is easily permeated into the living body and is reflected from the inside (for example, a vein) with information absorbed from the inside (one-dot chain line) and is emitted to the outside, and the reflected light (broken line) is also generated on the surface of the object. At this time, since the reflected light from the inside is depolarized by the internal scattering, the reflected light is transmitted through the polarizing plate 12 according to the embodiment of the present invention without being shielded by the polarizing plate 12 according to the embodiment of the present invention, and can be incident on the camera 62 having the infrared light receiving section (infrared imaging element) to obtain the information inside the object. On the other hand, since the reflected light from the surface maintains the polarization state, the reflected light is shielded by the polarizing plate 12 according to the embodiment of the present invention and is not imaged.

The imaging system according to the embodiment of the present invention can be preferably used in a case where there is a use for observing the visible image and the infrared image at the same position and the same time, in a case where it is desired to acquire the information inside the object with high accuracy by the infrared light, and in a case where it is desired to further reduce the size of the imaging system.

In a case in which the visible image and the infrared image are imaged by the visible imaging element and the infrared imaging element installed at different positions, the images imaged from different directions are added, the apparatus is complicated, or it is difficult to obtain the information on the same time. In addition, in a case where, for example, vein information in a living body is to be acquired with high sensitivity by the infrared light, it is preferable to use a system that excludes the surface reflected light that does not include the information because the surface reflected light is noise.

In the imaging system according to the embodiment of the present invention, since the image of the visible light and the infrared light can be acquired by one imaging element, the above-described problem can be overcome, and the surface reflection component of the infrared light can be removed by the polarization, so that the internal information can be detected with higher accuracy.

For example, by performing multi-wavelength imaging on a face image, information such as blood pressure, heart rate, stress state, respiratory rate, and face authentication can be obtained (for example, Monthly Functional Materials, November 2022, Vol. 41, No. 11, pp. 10 to 19, and the like). At this time, by using the imaging system according to the embodiment of the present invention, it is possible to acquire the blood flow information inside the face with higher accuracy.

In the above-described example, the apparatus is large-scale, but the visible imaging element and the infrared imaging element can also be used to capture images of the same object by the light (visible light and infrared light) on the same optical axis after passing through the polarizing plate 12 and the camera lens in a spectral manner without using the IR-RGB imaging element. In this case, the apparatus is complicated, but there is an advantage that the imaging element can be easily made high in pixels at low cost.

As a light source used in the imaging system, an LED can be preferably used. In a case of being implemented in a smartphone or the like, it is also preferable to use an attached infrared light source in combination.

### EXAMPLES

Hereinafter, features of the present invention will be described in more detail with reference to Examples and Comparative Examples. The materials, amounts used, proportions, treatment details, and treatment procedure shown in the following Examples can be appropriately changed without departing from the spirit and scope of the present invention. Accordingly, the scope of the present invention should not be construed as being limited by the specific examples given below.

### Synthesis

The following rod-like compound I-1 and dichroic coloring agents II-1 to II-3 having a hydrophilic group were synthesized by known methods. The rod-like compound I-1 was a polymer (n was 2 or more), a number-average molecular weight of the rod-like compound I-1 was 24,000, and a molecular weight distribution thereof was 6.8.

In addition, all of the dichroic coloring agents II-1 to II-3 exhibited lyotropic liquid crystallinity.

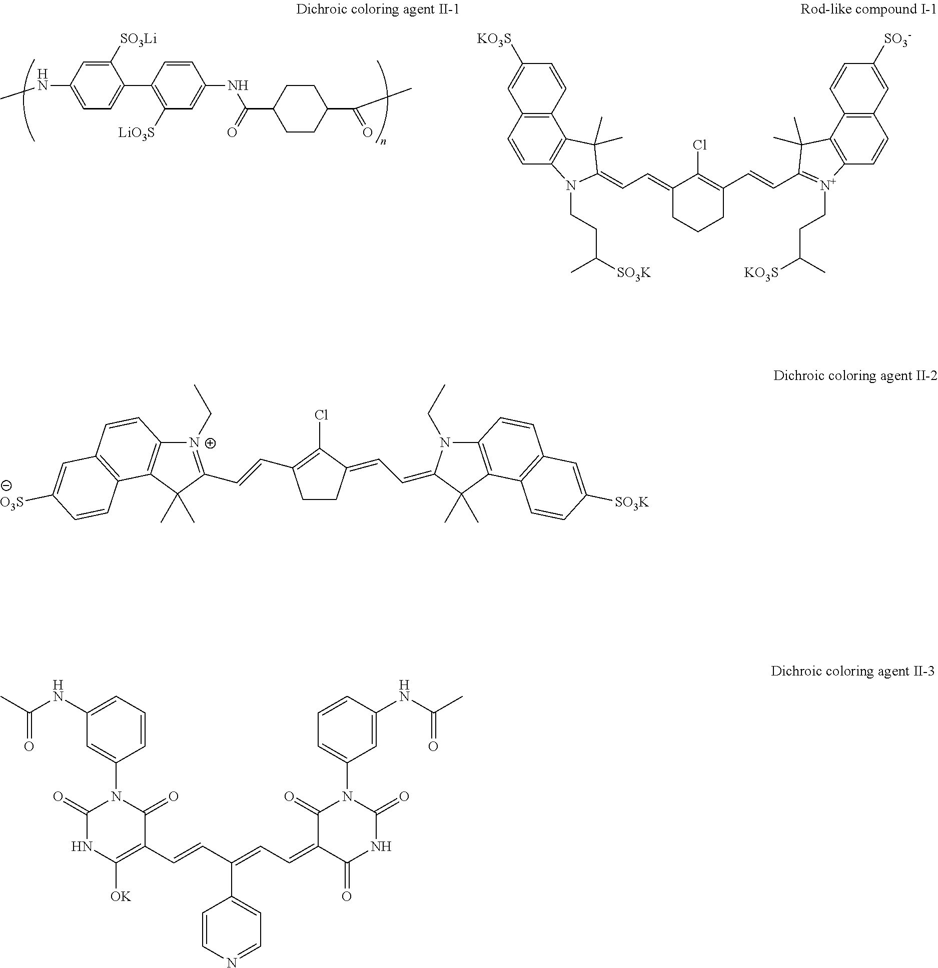

### <Production of Saponified Cellulose Acylate Film>

After passing a cellulose acylate film (TG40 manufactured by FUJIFILM Corporation) through a dielectric heating roll at a temperature of 60° C. to raise the film surface temperature to 40° C., an alkaline solution having the composition shown below was applied onto a band surface of the film using a bar coater at a coating amount of 14 ml/m², followed by heating to 110° C. and transportation of the film under a steam toe far-infrared heater manufactured by Noritake Company Limited for 10 seconds. Subsequently, pure water was applied at 3 ml/m² using the same bar coater. Next, the film was washed with water by a fountain coater and drained by an air knife three times, and then transported to a drying zone at 70° C. for 10 seconds and dried to produce a cellulose acylate film subjected to an alkali saponification treatment.

Alkaline solution

| | |
|---|---|
| Potassium hydroxide | 4.7 parts by mass |
| Water | 15.8 parts by mass |
| Isopropanol | 63.7 parts by mass |
| Surfactant: C₁₄H₂₉O(CH₂CH₂O)2₀H | 1.0 part by mass |
| Propylene glycol | 14.8 parts by mass |

### <Production of Polarizing Plate A>

The rod-like compound I-1 (10 parts by mass) was added to a solution of the dichroic coloring agent II-1 (0.8 parts by mass), which had been prepared by adding pure water (95 parts by mass) thereto and stirring the mixture for 10 minutes, and the mixture was further stirred for 30 minutes to prepare a composition A. Subsequently, the composition A (5 g) and Φ2 mm zirconia beads (20 g) were charged in a 45 mL zirconia container, and a milling treatment was performed for 10 minutes using a ball mill (planetary ball mill P-7 classic line, manufactured by Fritsch GmbH) at a rotation speed of 300 rpm to prepare a polarizing plate coating liquid A. The polarizing plate coating liquid A was a composition exhibiting lyotropic liquid crystallinity.

The above-described polarizing plate coating liquid A was applied onto the saponified surface of the above-described cellulose acylate film, which had been subjected to the alkali saponification treatment, using a wire bar #4 (transfer rate: 100 cm/s), and naturally dried. Next, the obtained coating film was immersed in a 1 mol/L calcium chloride aqueous solution for 5 seconds, washed with ion exchange water, and blast-dried to fix the alignment state, thereby producing a polarizing plate A having a film thickness of 0.2 μm.

The film thickness was measured using ultra-high resolution non-contact 3D surface shape measurement system BW-A501 manufactured by Nikon Corporation.

Using an ultraviolet-visible-near infrared spectrophotometer V-660, a transmittance T(λ) of the polarizing plate A at a wavelength λ was measured at a pitch of 1 nm. The polarizing plate A had one absorption maximal in a wavelength range of 800 to 1,500 nm, and a maximal absorption wavelength λmax was 931 nm. By averaging the transmittance at a wavelength of 400 to 700 nm, the average transmittance T(400-700) was calculated to be 90%.

Using an ultraviolet-visible-near infrared spectrophotometer V-660 equipped with an automatic absolute reflectivity measuring unit ARMN-735 manufactured by JASCO Corporation), a transmittance Tz(λ) of the polarizing plate A with respect to an absorption axis direction polarization at a wavelength λ and a transmittance Ty(λ) of the polarizing plate A with respect to a transmission axis direction polarization at the wavelength λ were measured in a wavelength range of 400 to 1,500 nm. Subsequently, a polarization degree P(λ) was obtained by the following expression. The absorption axis and the transmission axis described above mean an absorption axis and a transmission axis at a maximal absorption wavelength.

$$P ( λ ) = \{ ( Ty ( λ ) - Tz ( λ ) ) / ( Ty ( λ ) + Tz ( λ ) ) \} \times 100$$

The maximum value Pmax of the polarization degree P(λ) was 97.0%, and the wavelength λ1 at which the polarization degree was maximized was 954 nm. A transmittance T(λ1) at the wavelength λ1 was 42%.

In addition, in a case where an alignment degree S of the dichroic coloring agent was obtained by the following expression, it was 0.918.

$$S = ( Az ( λ1 ) - Ay ( λ1 ) ) / \{ Az ( λ1 ) + ( 2 \times Ay ( λ1 ) ) \} \\ Ay ( λ1 ) = - Log ( Ty ( λ1 ) ) \\ Az ( λ1 ) = - Log ( Tz ( λ1 ) )$$

### <Production of Polarizing Plate B>

A polarizing plate B was produced by the same method as the method for producing the polarizing plate A, except that the amount of the dichroic coloring agent II-1 used was changed from 0.8 parts by mass to 1.5 parts by mass. Evaluation results of optical characteristics of the polarizing plate B are shown in Table 1 described later.

### <Preparation of Polarizing Plate C>

A polarizing plate C was produced by the same method as the method for producing the polarizing plate A, except that the amount of the dichroic coloring agent II-1 used was changed from 0.8 parts by mass to 0.5 parts by mass. Evaluation results of optical characteristics of the polarizing plate C are shown in Table 1 described later.

### <Production of Polarizing Plate D>

A polarizing plate D was produced by the same method as the method for producing the polarizing plate A, except that the amount of the dichroic coloring agent II-1 used was changed from 0.8 parts by mass to 0.4 parts by mass. Evaluation results of optical characteristics of the polarizing plate D are shown in Table 1 described later.

### <Production of Polarizing Plate E>

A polarizing plate E was produced by the same method as the method for producing the polarizing plate A, except that the amount of the dichroic coloring agent II-1 used was changed from 0.8 parts by mass to 2.4 parts by mass. Evaluation results of optical characteristics of the polarizing plate E are shown in Table 1 described later.

### <Production of Polarizing Plate F>

The rod-like compound I-1 (10 parts by mass) was added to a solution of the dichroic coloring agent II-1 (0.8 parts by mass), which had been prepared by adding pure water (90 parts by mass) and dimethyl sulfoxide (5 parts by mass) thereto and stirring the mixture for 10 minutes, and the mixture was further stirred for 30 minutes to prepare a composition F. A polarizing plate F was produced by the same method as the method for producing the polarizing plate A, except that the composition A was changed to the composition F. Evaluation results of optical characteristics of the polarizing plate F are shown in Table 1 described later.

### <Production of Polarizing Plate G>

The rod-like compound I-1 (10 parts by mass) was added to a solution of the dichroic coloring agent II-1 (1.9 parts by mass), which had been prepared by adding pure water (85 parts by mass) and dimethyl sulfoxide (10 parts by mass) thereto and stirring the mixture for 10 minutes, and the mixture was further stirred for 30 minutes to prepare a composition G. A polarizing plate G was produced by the same method as the method for producing the polarizing plate A, except that the composition A was changed to the composition G. Evaluation results of optical characteristics of the polarizing plate G are shown in Table 1 described later.

### <Production of Polarizing Plate H>

The dichroic coloring agent II-3 (0.6 parts by mass) was mixed with pure water (100 parts by mass) by stirring for 10 minutes to obtain a coloring agent dispersion liquid 1. Subsequently, the coloring agent dispersion liquid 1 (20 g) and Φ0.1 mm zirconia beads (40 g) were charged in a 45 mL zirconia container, and a milling treatment was performed for 20 minutes using a ball mill (planetary ball mill P-7 classic line, manufactured by Fritsch GmbH) at a rotation speed of 600 rpm to prepare a coloring agent dispersion liquid 2.

Next, the above-described coloring agent dispersion liquid 2 (100 parts by mass) was added to the dichroic coloring agent II-1 (0.6 parts by mass), and the mixture was stirred and mixed for 10 minutes, and then the rod-like compound I-1 (10 parts by mass) was added thereto to obtain a composition H.

Subsequently, the composition H (5 g) and Φ5 mm zirconia beads (20 g) were charged in a 45 mL zirconia container, and a milling treatment was performed for 50 minutes using a ball mill (planetary ball mill P-7 classic line, manufactured by Fritsch GmbH) at a rotation speed of 300 rpm to prepare a polarizing plate coating liquid H. The polarizing plate coating liquid H was a composition exhibiting lyotropic liquid crystallinity.

A polarizing plate H was produced by the same method as the method for producing the polarizing plate A, except that the polarizing plate coating liquid A was changed to the polarizing plate coating liquid H.

### <Production of Polarizing Plate I>

A polarizing plate I was produced by the same method as the method for producing the polarizing plate H, except that the amount of the dichroic coloring agent II-3 used was changed from 0.6 parts by mass to 1.5 parts by mass, and the amount of the dichroic coloring agent II-1 used was changed from 0.6 parts by mass to 1.5 parts by mass.

### <Production of Polarizing Plate J>

The dichroic coloring agent II-1 (1.0 part by mass) and the dichroic coloring agent II-3 (1.0 part by mass) was mixed with pure water (95 parts by mass) by stirring for 10 minutes. Subsequently, the rod-like compound I-1 (10 parts by mass) was added to the obtained composition, and the mixture was further stirred for 30 minutes to obtain a composition J.

A polarizing plate J was produced by the same method as the method for producing the polarizing plate A, except that the composition A was changed to the composition J.

### <Production of Polarizing Plate K>

A polarizing plate K was produced by the same method as the method for producing the polarizing plate A, except that the dichroic coloring agent II-1 (0.8 parts by mass) was changed to the dichroic coloring agent II-2 (0.3 parts by mass).

### <Production of Polarizing Plate L>

A polarizing plate L was produced by the same method as the method for producing the polarizing plate K, except that the amount of the dichroic coloring agent II-2 used was changed from 0.3 parts by mass to 0.1 parts by mass.

### Example 1

### (Evaluation of Iris Detection)

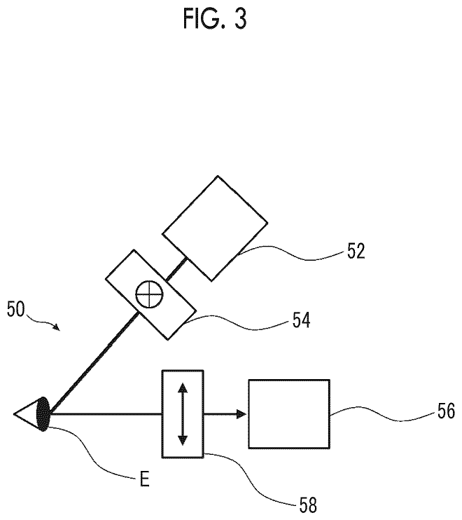

Using an apparatus 50 shown in FIG. 3, which was modeled on a head-mounted display having an iris authentication system, evaluation of the iris detection was performed.

The apparatus 50 includes an infrared light source 52, a polarizing plate 54 disposed on an emission side of the infrared light source 52, an infrared light receiving section 56, and a polarizing plate 58 disposed on a front surface of the infrared light receiving section 56. Light emitted from the infrared light source 52 is transmitted through the polarizing plate 54, incident on an eyeball E of an observer, and the light reflected by the eyeball E is transmitted through the polarizing plate 58 and received by the infrared light receiving section 56. As the polarizing plate 54 and the polarizing plate 58, the above-described polarizing plate A was used, and as shown in FIG. 3, the polarizing plates A were arranged such that absorption axes of the two polarizing plates were in a crossed-nicol disposition in which the absorption axes of the two polarizing plates were orthogonal to each other. As the infrared light source, an LED lamp (WindFire Mini IR Lamp Zoomable 5W 850 nm/940 nm LED Infrared Flashlight Night Vision) having a wavelength of 940 nm was used, and the imaging was performed using an Edmund E0-camera (corresponding to the infrared light receiving section) equipped with a visible light cut filter (Fujifilm IR80). Since the image was darkened by insertion of the polarizing plates A, the light source intensity was adjusted to be the same as the brightness in a case of the absence of the polarizing plates A, and the images were compared at the same shutter speed.

Iris detection performance was evaluated based on the following standard.
A: the entire region of the iris pattern was clearly detected.
B: the entire region of the iris pattern was detected, but the detection was somewhat unclear.
C: there was a region where the iris pattern could not be detected, which was unacceptable.

### (Evaluation of Display Performance)

The polarizing plate A was installed on a visual side of a display unit of a commercially available head-mounted display HOLOLENS2 (manufactured by Microsoft Corporation), and white display was evaluated according to the following standard.
A: the brightness and the tint were the same as compared with a case in which the polarizing plate was not installed, and the display performance was excellent.
B: the image was slightly darker and had a tint as compared with a case in which the polarizing plate was not installed, but it was acceptable.
C: the image was dark, which was not acceptable.

### (Evaluation of Workability)

The surface of the polarizing plate A was bonded to glass using a pressure sensitive adhesive, and the obtained laminate was evaluated according to the following standard.
A: no cracks occurred in the polarizing plate, and the polarizing plate was uniformly bonded.
B: a crack occurred at an end part of the polarizing plate.
C: cracks occurred on the entire surface of the polarizing plate, which was not acceptable.

### Comparative Example 1

Various evaluations were carried out according to the same procedure as in Example 1, except that the polarizing plate A was not installed.

### Examples 2 to 8 and Comparative Examples 2 to 6

As shown in the following table, various evaluations were carried out according to the same procedure as in Example 1, except that the polarizing plate A was changed to the polarizing plates B to L, respectively.

In Example 7, the same evaluation of the iris detection performance was performed, in which the wavelength of the light source was changed from 940 nm to 850 nm.

In Table 1, the column of “T(400-700)” indicates the average transmittance of the polarizing plate at a wavelength of 400 to 700 nm.

In Table 1, the column of “Maximal absorption wavelength (nm)” indicates the maximal absorption wavelength of the dichroic substance.

In Table 1, the column of “Maximum polarization degree Pmax” indicates the maximum value of the polarization degree of the polarizing plate at a wavelength of 800 to 1,500 nm.

In Table 1, the column of “λ1 (nm)” indicates the wavelength showing the maximum value of the polarization degree.

In Table 1, the column of “Transmittance T(λ1)” indicates the transmittance of the polarizing plate at the wavelength λ1.

In Table 1, the column of “S(λ1)” indicates the alignment degree of the dichroic coloring agent at the wavelength λ1.

In Table 1, the column of “λ2 (nm)” indicates the maximal wavelength of the infrared light emitted from the light source.

In Table 1, the column of “|λ1−λ2| (nm)” indicates the difference between λ1 and λ2.

TABLE 1

| | | | Maximal | | | | | | | | | |
|---|---|---|---|---|---|---|---|---|---|---|---|---|
| | | | absorption | Maximum | | | | | \|λ1 − | | | |
| | | T(400- | wavelength | polarization | λ1 | Transmittance | | λ2 | λ2\| | Iris | Display | |
| | Type | 700) | (nm) | degree Pmax | (nm) | T(λ1) | S(λ1) | (nm) | (nm) | detection | performance | Workability |
| Comparative | — | — | — | — | — | — | — | — | — | C | A | — |
| Example 1 | | | | | | | | | | | | |
| Example 1 | Polarizing | 90% | 931 | 97.0% | 954 | 42% | 0.918 | 940 | 14 | A | A | A |
| | plate A | | | | | | | | | | | |
| Example 2 | Polarizing | 83% | 924 | 99.9% | 954 | 34% | 0.918 | 940 | 14 | B | B | A |
| | plate B | | | | | | | | | | | |
| Example 3 | Polarizing | 94% | 942 | 81.9% | 954 | 47% | 0.918 | 940 | 14 | B | A | A |
| | plate C | | | | | | | | | | | |
| Comparative | Polarizing | 95% | 945 | 78.1% | 954 | 51% | 0.918 | 940 | 14 | C | A | A |
| Example 2 | plate D | | | | | | | | | | | |
| Comparative | Polarizing | 76% | 923 | >99.9% | 954 | 28% | 0.918 | 940 | 14 | C | B | A |
| Example 3 | plate E | | | | | | | | | | | |
| Example 4 | Polarizing | 91% | 953 | 97.1% | 954 | 43% | 0.934 | 940 | 14 | A | A | B |
| | plate F | | | | | | | | | | | |
| Example 5 | Polarizing | 81% | 953 | >99.9% | 954 | 39% | 0.958 | 940 | 14 | A | A | C |
| | plate G | | | | | | | | | | | |
| Example 6 | Polarizing | 83% | 934.847 | 95.0% | 949 | 42% | 0.875 | 940 | 9 | A | B | A |
| | plate H | | | | | | | | | | | |
| Example 7 | Polarizing | 83% | 934.847 | 95.0% | 949 | 42% | 0.875 | 850 | 99 | B | B | A |
| | plate H | | | | | | | | | | | |
| Comparative | Polarizing | 68% | 924.847 | >99.9% | 949 | 31% | 0.875 | 940 | 9 | B | C | A |
| Example 4 | plate I | | | | | | | | | | | |
| Example 8 | Polarizing | 78% | 939.841 | 91.2% | 946 | 30% | 0.721 | 940 | 6 | B | B | A |
| | plate J | | | | | | | | | | | |
| Comparative | Polarizing | 97% | 965 | 96.9% | 956 | 24% | 0.653 | 940 | 16 | C | A | A |
| Example 5 | plate K | | | | | | | | | | | |
| Comparative | Polarizing | 99% | 959 | 66.1% | 956 | 45% | 0.653 | 940 | 16 | C | A | A |
| Example 6 | plate L | | | | | | | | | | | |

From the above results, it was found that the polarizing plate according to the embodiment of the present invention had a desired effect.

More specifically, from the comparison between Example 1 and Comparative Example 1, it was found that, by applying the polarizing plate according to the claim 1, the reflected light on the eye surface was removed, and the iris detection performance was improved.

From Comparative Example 2, in a case where the polarization degree P was 80% or less and the transmittance T(λ1) was more than 50%, it is considered that the reflected light could not be removed and the iris detection performance was insufficient.

In Comparative Example 3, even in a case where the light source intensity was increased to the maximum, the brightness was not sufficiently increased, and a clear image of the iris was not obtained. From this, in a case where the transmittance T(λ1) was less than 30%, it was considered that the iris detection performance was insufficient.

From Comparative Example 4, it was found that, in a case where the average transmittance T(400-700) was 70% or less, the display performance was deteriorated.

From the comparison between Example 5 and other examples, it was found that, in a case where the alignment degree S(λ1) was 0.950 or less, the workability was improved.

From the comparison between Examples 6 and 7, it was found that the effect was more excellent in a case where the difference between the wavelength λ1 and the wavelength λ2 was 20 nm.

### Example 8

### (Evaluation of Face Detection)

The polarizing plate A was installed on a display of a commercially available smartphone (Galaxy Z Fold3 5G manufactured by SAMSUNG) at an angle (0°) at which the absorption axis was parallel to a major axis of the smartphone. The above-described absorption axis is an absorption axis of the polarizing plate at the maximal absorption wavelength (wavelength: 931 nm). In order to extract only the infrared image, a visible light cut filter (Fujifilm IR80) was installed on the polarizing plate A, an LED lamp (WindFire Mini IR Lamp Zoomable 5W 850 nm/940 nm LED Infrared Flashlight Night Vision) having a wavelength of 940 nm was used as a light source, and a camera installed under the display of the smartphone was used to image a human face. Subsequently, the absorption axis of the polarizing plate A was replaced with an angle (90°) orthogonal to the major axis of the smartphone, and the same imaging was performed. In a case where the positions of the two captured images were corrected, a brightness difference AY between the 0° image and the 90° image was calculated for 1,600 points of pixels, and a brightness ratio distribution a was calculated, it was 20.

Subsequently, in a case where the same person's image was similarly imaged at 0° and 90°, it was found that the brightness ratio distribution a was 2.5 or less and small, and that there was no polarization dependence. With this method, it was possible to distinguish between the human face and the image of the human face.

### (Evaluation of Display Performance)

The smartphone on which the polarizing plate A was installed on the display was allowed to display white, and the display was compared with a display in a case in which the polarizing plate A was not installed; and it was found that the brightness and the tint were substantially the same, the deterioration of the display performance did not occur, and the display performance was excellent.

### (Evaluation of Imaging Performance)

In a state in which the polarizing plate A was installed on the display of the smartphone, white paper on which 10.5-point black hiragana was printed in A4 was imaged under a fluorescent lamp using a display lower camera of the smartphone, and the obtained image was compared with an image obtained in a case in which the polarizing plate A was not installed, and it was found that the images were substantially the same, and the imaging performance was not affected and the imaging performance was excellent.

### Comparative Example 9

The face detection evaluation, the display performance evaluation, and the imaging performance evaluation were carried out by the same method as the method described in Example 8, except that the polarizing plate K was used instead of the polarizing plate A.

The brightness ratio distribution in a case in which the human face was imaged and the brightness ratio distribution in a case in which the image of the human face was imaged were the same, and were not suitable for the face detection.

### EXPLANATION OF REFERENCES

10: organic EL display device
12: polarizing plate
16: organic EL display element
18: infrared light source
20: infrared light receiving section
30: head-mounted display
32: display panel
34: display element
36: infrared light source
38: light guide element
40: emission surface
42: infrared light receiving section
50: apparatus
52: infrared light source
54: polarizing plate
56: infrared light receiving section
58: polarizing plate
60: imaging system
61: IR-RGB imaging element
62: IR-RGB camera
63: infrared light source
64: infrared polarizing plate
65: imaging object

What is claimed is:

1. A polarizing plate,
wherein an average transmittance at a wavelength of 400 to 700 nm is 70% or more,
a maximum value of a polarization degree at a wavelength of 800 to 1500 nm is 80% or more, and
in a case where a wavelength at which the polarization degree is the maximum value is defined as a wavelength λ1, a transmittance T(λ1) at the wavelength λ1 satisfies relationships of an expression (A1) and an expression (A2),

| | |
|---|---|
| the expression (A1) | 30% ≤ T(λ1), and |
| the expression (A2) | T(λ1) ≤ 50%. |

2. The polarizing plate according to claim 1,
wherein a relationship of an expression (A3) is satisfied,

| | |
|---|---|
| the expression (A3) | 40% ≤ T(λ1). |

3. The polarizing plate according to claim 1,
wherein a relationship of an expression (A4) is satisfied,

| | |
|---|---|
| the expression (A4) | T(λ1) ≤ 45%. |

4. The polarizing plate according to claim 1,
wherein the polarizing plate contains a dichroic coloring agent having a maximal absorption wavelength at the wavelength of 800 to 1500 nm, and
an alignment degree S(λ1) of the dichroic coloring agent at the wavelength λ1 satisfies relationships of an expression (B1) and an expression (B2),

| | |
|---|---|
| the expression (B1) | 0.700 ≤ S(λ1), and |
| the expression (B2) | S(λ1) ≤ 0.950. |

5. The polarizing plate according to claim 4,
wherein a relationship of an expression (B3) is satisfied,

| | |
|---|---|
| the expression (B3) | 0.850 ≤ S(λ1). |

6. The polarizing plate according to claim 4,
wherein a relationship of an expression (B4) is satisfied,

| | |
|---|---|
| the expression (B4) | S(λ1) ≤ 0.930. |

7. An apparatus comprising:
the polarizing plate according to claim 1;
at least one of a display element or a visible light imaging element; and
an infrared light receiving section.

8. An apparatus according to claim 7, further comprising:
an infrared light source,
wherein a difference between the λ1 and a maximal wavelength λ2 of an infrared light emitted from the infrared light source is 20 nm or less.

9. Ahead-mounted display comprising:
the apparatus according to claim 7.

10. An organic electroluminescent display device comprising:
the apparatus according to claim 7.

11. An imaging system comprising:
the apparatus according to claim 7.

12. An apparatus comprising:
the polarizing plate according to claim 1;
an infrared light and visible light dual-purpose imaging element; and
an infrared light source.

13. An apparatus according to claim 12, further comprising:
an infrared light source,
wherein a difference between the λ1 and a maximal wavelength λ2 of an infrared light emitted from the infrared light source is 20 nm or less.

14. The polarizing plate according to claim 2,
wherein a relationship of an expression (A4) is satisfied,

| | |
|---|---|
| the expression (A4) | T(λ1) ≤ 45%. |

15. The polarizing plate according to claim 2,
wherein the polarizing plate contains a dichroic coloring agent having a maximal absorption wavelength at the wavelength of 800 to 1500 nm, and
an alignment degree S(λ1) of the dichroic coloring agent at the wavelength λ1 satisfies relationships of an expression (B1) and an expression (B2),

| | |
|---|---|
| the expression (B1) | 0.700 ≤ S(λ1), and |
| the expression (B2) | S(λ1) ≤ 0.950. |

16. The polarizing plate according to claim 15,
wherein a relationship of an expression (B3) is satisfied,

| | |
|---|---|
| the expression (B3) | 0.850 ≤ S(λ1). |

17. The polarizing plate according to claim 5,
wherein a relationship of an expression (B4) is satisfied,

| | |
|---|---|
| the expression (B4) | S(λ1) ≤ 0.930. |

18. The polarizing plate according to claim 15,
wherein a relationship of an expression (B4) is satisfied,

| | |
|---|---|
| the expression (B4) | S(λ1) ≤ 0.930. |

19. An apparatus comprising:
the polarizing plate according to claim 2;
at least one of a display element or a visible light imaging element; and
an infrared light receiving section.

20. An apparatus according to claim 19, further comprising:
an infrared light source,
wherein a difference between the λ1 and a maximal wavelength λ2 of an infrared light emitted from the infrared light source is 20 nm or less.
